(19) United States
(12) Patent Application Publication
(10) Pub. No.: US 2025/0393419 A1
(43) Pub. Date: Dec. 25, 2025

(54) DISPLAY APPARATUS

(71) Applicant: Samsung Display Co., LTD., Yongin-si (KR)

(72) Inventors: Nuree UM, Yongin-si (KR); Yujin JEON, Yongin-si (KR); Younghoon JO, Yongin-si, (KR); Jaewon CHO, Yongin-si (KR)

(21) Appl. No.: 19/068,400

(22) Filed: Mar. 3, 2025

(30) Foreign Application Priority Data
Jun. 20, 2024 (KR) 10-2024-0080202

(51) Int. Cl. H10K 59/131; H10K 59/124

(52) U.S. Cl. CPC H10K 59/131; H10K 59/124

(57) ABSTRACT

A display apparatus includes a substrate including a display area and a peripheral area including a pad area, an inorganic insulating layer disposed on the substrate, a light-emitting element layer including a light-emitting element, a power voltage line arranged between the pad area and the display area in a plan view and including an opening portion, and a fan-out line extending from the pad area to the display area and overlapping at least a portion of the power voltage line in a plan view, wherein the fan-out line includes a first sub-line disposed on the inorganic insulating layer, a second sub-line inserted into the inorganic insulating layer, and a contact portion to which the first sub-line and the second sub-line are electrically connected, wherein the contact portion of the fan-out line is positioned within the opening portion of the power voltage line in a plan view.

This application claims priority to Korean Patent Application No. 10-2024-0080202, filed on Jun. 20, 2024, and all the benefits accruing therefrom under 35 U.S.C. § 119, the content of which in its entirety is herein incorporated by reference.

### BACKGROUND

### 1. Field

The invention relates to a display apparatus.

### 2. Description of the Related Art

A display apparatus visually displays data. Such a display apparatus includes a substrate divided into a display area and a peripheral area located outside of the display area. In the display area, a scan line and a data line are formed to be insulated from each other, and a plurality of pixels connected to the scan line and the data line are arranged. In addition, a transistor and a pixel electrode electrically connected to the transistor are included in the display area, wherein the transistor and the pixel electrode correspond to each of the plurality of pixels. Also, an opposite electrode commonly provided in the pixels is included in the display area. The peripheral area may include various lines configured to transmit an electrical signal to the display area, a scan driving unit, a data driving unit, a controller, or the like. Such display apparatuses have become more diversified in use.

### SUMMARY

One or more embodiments include a display apparatus with a reduced peripheral area and excellent display quality. However, these objectives are examples, and the scope of the invention is not limited thereto.

Additional aspects will be set forth in part in the description which follows and, in part, will be apparent from the description, or may be learned by practice of the presented invention.

According to one or more embodiments, a display apparatus includes a substrate including a display area and a peripheral area including a pad area arranged outside of the display area, an inorganic insulating layer disposed on the substrate, a light-emitting element layer disposed on the inorganic insulating layer and including a light-emitting element overlapping the display area in a plan view, a power voltage line arranged between the pad area and the display area in a plan view and including an opening portion, and a fan-out line extending from the pad area to the display area and overlapping at least a portion of the power voltage line in a plan view, wherein the fan-out line includes a first sub-line disposed on the inorganic insulating layer, a second sub-line inserted into the inorganic insulating layer, and a contact portion in which the first sub-line and the second sub-line are electrically connected, wherein the contact portion of the fan-out line is positioned within the opening portion of the power voltage line in a plan view.

In an embodiment, the display apparatus may further include an organic insulating layer disposed on the inorganic insulating layer and including a first organic insulating layer and a second organic insulating layer, which are sequentially stacked, wherein the inorganic insulating layer may include a first inorganic insulating layer, a second inorganic insulating layer, and a third inorganic insulating layer, which are sequentially stacked, wherein the first sub-line of the fan-out line may be arranged between the inorganic insulating layer and the first organic insulating layer or between the first organic insulating layer and the second organic insulating layer, and wherein the second sub-line of the fan-out line may be arranged between the first inorganic insulating layer and the second inorganic insulating layer or between the second inorganic insulating layer and the third inorganic insulating layer.

In an embodiment, the display apparatus may further include a semiconductor layer overlapping the display area in a plan view and may be arranged between the substrate and the first inorganic insulating layer, and a gate electrode overlapping the semiconductor layer in a plan view and arranged between the first inorganic insulating layer and the second inorganic insulating layer.

In an embodiment, the fan-out line may include first fan-out lines and second fan-out lines, which are alternately arranged, wherein a first sub-line of each of the first fan-out lines may be disposed on a different layer from a first sub-line of each of the second fan-out lines, and wherein a second sub-line of each of the first fan-out lines may be disposed on a different layer from a second sub-line of each of the second fan-out lines.

In an embodiment, the power voltage line may include a first sub-power voltage line inserted into the inorganic insulating layer, and a second sub-power voltage line disposed on the inorganic insulating layer and electrically connected to the first sub-power voltage line, wherein the first sub-power voltage line of the power voltage line may overlap the first sub-line of the fan-out line in a plan view, and wherein the second sub-power voltage line of the power voltage line may overlap the second sub-line of the fan-out line in a plan view.

In an embodiment, the opening portion of the power voltage line may be positioned in the first sub-power voltage line of the power voltage line.

In an embodiment, the inorganic insulating layer may further include a fourth inorganic insulating layer disposed on the third inorganic insulating layer, and the first sub-power voltage line of the power voltage line may be arranged between the third inorganic insulating layer and the fourth inorganic insulating layer.

In an embodiment, a width of the power voltage line may be greater than a width of the fan-out line.

In an embodiment, the display apparatus may further include a sealing substrate disposed on the light-emitting element layer, and a sealing member arranged between the substrate and the sealing substrate and surrounding the display area in a plan view, wherein the fan-out line may extend across the sealing member in a plan view, and wherein the contact portion of the fan-out line may be positioned between the sealing member and the pad area.

In an embodiment, the display apparatus may further include an encapsulation layer disposed on the light-emitting element layer and including at least one inorganic encapsulation layer and at least one organic encapsulation layer.

In an embodiment, the fan-out line may include a plurality of fan-out lines, the power voltage line may include a plurality of opening portions, and the contact portion of each of the fan-out lines may be positioned within a corresponding opening portion among the plurality of opening portions.

According to one or more embodiments, a display apparatus includes a substrate including a display area, and a peripheral area including a pad area arranged outside of the display area, an inorganic insulating layer disposed on the substrate, a light-emitting element layer disposed on the inorganic insulating layer and including a light-emitting element overlapping the display area in a plan view, a power voltage line arranged between the pad area and the display area in a plan view, and a fan-out line extending from the pad area to the display area and overlapping at least a portion of the power voltage line in a plan view, wherein the fan-out line may include a first sub-line disposed on the inorganic insulating layer, a second sub-line inserted into the inorganic insulating layer, and a contact portion in which the first sub-line and the second sub-line are electrically connected, the power voltage line may include a first sub-power voltage line inserted into the inorganic insulating layer, and a second sub-power voltage line disposed on the inorganic insulating layer and electrically connected to the first sub-power voltage line, wherein the first sub-power voltage line of the power voltage line may overlap the first sub-line of the fan-out line in a plan view, the second sub-power voltage line of the power voltage line may overlap the second sub-line of the fan-out line in a plan view, and the first sub-power voltage line of the power voltage line may be disposed on a different layer from the first sub-line of the fan-out line.

In an embodiment, the display apparatus may further include an organic insulating layer disposed on the inorganic insulating layer and including a first organic insulating layer and a second organic insulating layer, which are sequentially stacked, wherein the inorganic insulating layer may include a first inorganic insulating layer, a second inorganic insulating layer, and a third inorganic insulating layer, which are sequentially stacked, wherein the first sub-line of the fan-out line may be arranged between the inorganic insulating layer and the first organic insulating layer or between the first organic insulating layer and the second organic insulating layer, and the second sub-line of the fan-out line may be arranged between the first inorganic insulating layer and the second inorganic insulating layer or between the second inorganic insulating layer and the third inorganic insulating layer.

In an embodiment, the display apparatus may further include a semiconductor layer overlapping the display area in a plan view and arranged between the substrate and the first inorganic insulating layer, and a gate electrode overlapping the semiconductor layer in a plan view and arranged between the first inorganic insulating layer and the second inorganic insulating layer.

In an embodiment, the inorganic insulating layer may further include a fourth inorganic insulating layer disposed on the third inorganic insulating layer, wherein the first sub-power voltage line of the power voltage line may be arranged between the third inorganic insulating layer and the fourth inorganic insulating layer.

In an embodiment, the first sub-power voltage line of the power voltage line may include an opening portion.

In an embodiment, the contact portion of the fan-out line may be positioned within the opening portion of the first sub-power voltage line in a plan view.

In an embodiment, the fan-out line may include first fan-out lines and second fan-out lines, which are alternately arranged, wherein a first sub-line of each of the first fan-out lines may be disposed on a different layer from a first sub-line of each of the second fan-out lines, and a second sub-line of each of the first fan-out lines may be disposed on a different layer from a second sub-line of each of the second fan-out lines.

In an embodiment, the display apparatus may further include a sealing substrate disposed on the light-emitting element layer, and a sealing member arranged between the substrate and the sealing substrate and surrounding the display area in a plan view, wherein the fan-out line may extend across the sealing member in a plan view, and wherein the contact portion of the fan-out line may be positioned between the sealing member and the pad area.

In an embodiment, the display apparatus may further include an encapsulation layer disposed on the light-emitting element layer and including at least one inorganic encapsulation layer and at least one organic encapsulation layer.

### BRIEF DESCRIPTION OF THE DRAWINGS

The above and other aspects, features, and advantages of certain embodiments of the invention will be more apparent from the following description taken in conjunction with the accompanying drawings, in which:

FIG. 1 is a schematic perspective view of a display apparatus, according to an embodiment;

FIG. 2A is a cross-sectional view schematically illustrating the display apparatus of FIG. 1, taken along a line A-A′ of FIG. 1, according to an embodiment;

FIG. 2B is a cross-sectional view schematically illustrating the display apparatus of FIG. 1, taken along a line A-A′ of FIG. 1, according to an embodiment;

FIG. 3A is a plan view schematically illustrating a display panel of a display apparatus, according to an embodiment;

FIG. 3B is a plan view schematically illustrating a display panel of a display apparatus, according to an embodiment;

FIG. 4A is an equivalent circuit diagram schematically illustrating a sub-pixel of a display panel, according to an embodiment;

FIG. 4B is an equivalent circuit diagram schematically illustrating a sub-pixel of a display panel, according to an embodiment;

FIG. 5 is an enlarged plan view of a region D of FIG. 3B, which is a portion of a display panel, according to an embodiment;

FIG. 6A is a plan view illustrating a portion of the display panel shown in FIG. 5;

FIG. 6B is a plan view illustrating a portion of the display panel shown in FIG. 5;

FIG. 6C is a plan view illustrating a portion of the display panel shown in FIG. 5;

FIG. 6D is a plan view illustrating a portion of the display panel shown in FIG. 5;

FIG. 6E is a plan view illustrating a portion of the display panel shown in FIG. 5.

FIG. 7 is a cross-sectional view of a portion of the display panel of FIG. 5 taken along a line I-I′ of FIG. 5, according to an embodiment;

FIG. 8 is a cross-sectional view of a portion of the display panel of FIG. 5 taken along a line II-II′ of FIG. 5, according to an embodiment;

FIG. 9 is a cross-sectional view of a portion of the display panel of FIG. 5 taken along a line III-III′ of FIG. 5, according to an embodiment;

FIG. 10 is a block diagram of an electronic device according to an embodiment;

FIG. 11 is schematic diagrams of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the invention. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the invention allows for various changes and numerous embodiments, particular embodiments will be illustrated in the drawings and described in detail in the written description. Effects and features of the invention and methods of achieving the same will be apparent with reference to embodiments and drawings described below in detail. The invention may, however, be embodied in many different forms and should not be construed as being limited to the embodiments set forth herein.

The invention will now be described more fully with reference to the accompanying drawings, in which embodiments of the invention are shown. Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including,” “having,” and “comprising” are intended to indicate the existence of the features, or elements disclosed in the specification, and are not intended to preclude the possibility that one or more other features or elements may exist or may be added.

Sizes of elements in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the present specification, “A and/or B” may include “A,” “B,” or “A and B.” In addition, “at least one of A and B” may include “A,” “B,” or “A and B.”

It will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

The x-axis, the y-axis, and the z-axis are not limited to three axes of the rectangular coordinate system and may be interpreted in a broader sense. For example, the x-axis, the y-axis, and the z-axis may be perpendicular to one another, or may represent different directions that are not perpendicular to one another.

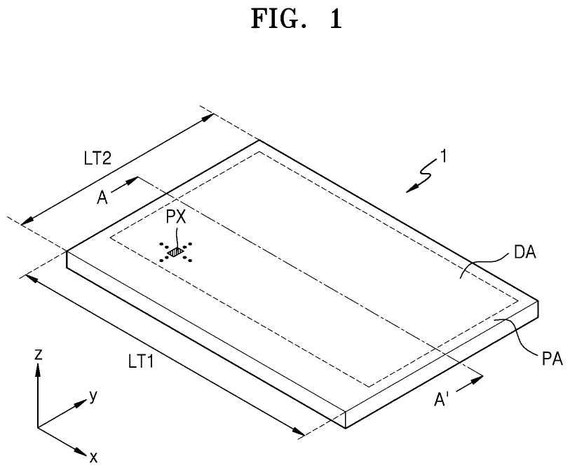

FIG. 1 is a schematic perspective view of a display apparatus 1, according to an embodiment.

In an embodiment and referring to FIG. 1, the display apparatus 1 may display an image and may include a display area DA and a peripheral area PA. A sub-pixel PX may be arranged in the display area DA. The peripheral area PA may at least partially surround the display area DA. The sub-pixel PX may not be arranged in the peripheral area PA.

FIG. 1 shows an embodiment where the display apparatus 1 includes the display area DA having a rectangular shape, but in another embodiment, the display area DA may have a circular shape, an oval shape, or a polygonal shape such as a triangular shape, a pentagonal shape, or the like. The display apparatus 1 of FIG. 1 is shown as a flat panel display apparatus, but the display apparatus 1 may be implemented in various forms such as a flexible, foldable, and rollable display apparatus.

In an embodiment, a plurality of sub-pixels PX may be arranged in the display area DA and may emit light, and the display apparatus 1 may display an image in the display area DA. In an embodiment, any one of the plurality of sub-pixels PX may emit red, green, or blue light. In another embodiment, any one of the plurality of sub-pixels PX may emit red, green, blue, or white light.

In an embodiment, a first length LT1 of the display apparatus 1 directed in a first direction may be greater than a second length LT2 of the display apparatus 1 directed in a second direction. The number of the plurality of sub-pixels PX arranged in the first direction may be greater than the number of the plurality of sub-pixels PX arranged in the second direction. Additionally, the first direction and the second direction may intersect with each other. For example, the first direction and the second direction may be directed perpendicular to each other, where the first direction may be directed in an x direction and the second direction may be directed in a y direction. As another example, the first direction and the second direction may form an acute angle with each other or may form an obtuse angle with each other. In another embodiment, the first length LT1 may be less than the second length LT2. In another embodiment, the first length LT1 may be equal to the second length LT2.

In an embodiment, the display apparatus 1 may include a liquid-crystal display apparatus, an electrophoretic display apparatus, an organic light-emitting display apparatus, an inorganic electroluminescence (EL) display apparatus, a field emission display apparatus, a surface-conduction electron-emitter display apparatus, a quantum dot display apparatus, a plasma display apparatus, a cathode ray display apparatus, or the like. Hereinafter, an organic light-emitting display apparatus is described as an example of the display apparatus 1, according to an embodiment, but various types of display apparatuses stated above may be used in other embodiments.

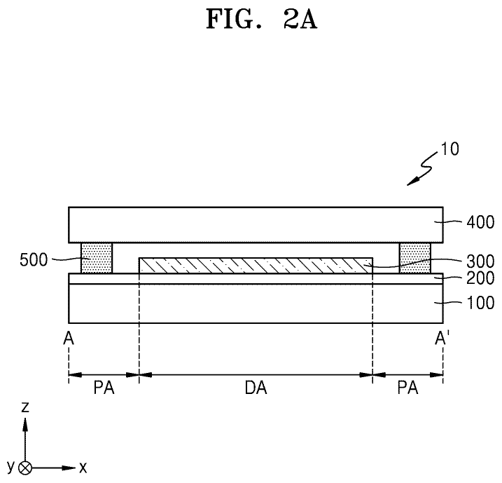

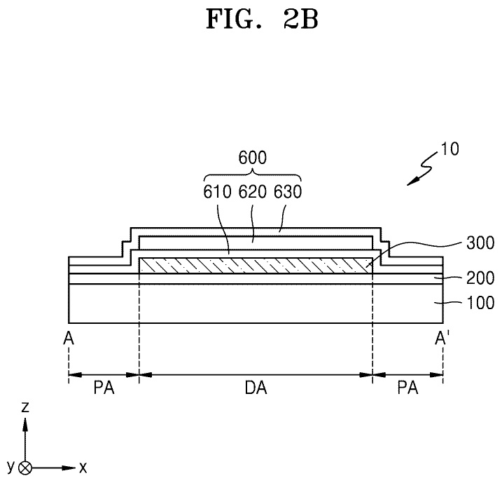

FIGS. 2A and 2B are cross-sectional views each schematically illustrating the display apparatus 1 of FIG. 1, taken along a line A-A′, according to an embodiment.

In an embodiment and referring to FIGS. 2A and 2B, the display apparatus 1 may include a display panel 10, a cover window, a housing, or the like. The display panel 10 may include a substrate 100, an inorganic insulating layer 200, a light-emitting element layer 300, and a sealing structure. The display apparatus 1 may include a display area DA and a peripheral area PA, where the display area DA and the peripheral area PA may be defined in the substrate 100. In other words, the substrate 100 may include the display area DA and the peripheral area PA.

In an embodiment, the substrate 100 may include a glass material or a polymer resin, wherein the polymer resin may include a polymer resin, such as polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. In an embodiment, the substrate 100 may have an alternating stacked structure of a base layer including a polymer resin and a barrier layer including an inorganic insulating material, such as silicon oxide or silicon nitride.

In an embodiment, the inorganic insulating layer 200 may be disposed on the substrate 100 and may overlap the display area DA and the peripheral area PA. In the disclosure, a first component and a second component overlapping each other means that the first component and the second component overlap each other in a plan view (e.g., an x-y plane). The inorganic insulating layer 200 may include an inorganic insulating material, such as silicon oxide, silicon nitride, silicon oxynitride, aluminum oxide, titanium oxide, tantalum oxide, hafnium oxide and/or zinc oxide, or the like. In an embodiment, the zinc oxide may include zinc oxide (ZnO) and/or zinc peroxide (ZnO₂).

In an embodiment, the light-emitting element layer 300 may be disposed on the inorganic insulating layer 200 and may overlap the display area DA. The light-emitting element layer 300 may include a light-emitting element which may be an organic light-emitting diode including an organic emission layer. In another embodiment, the light-emitting element may be an inorganic light-emitting diode including an inorganic emission layer. The size of the inorganic light-emitting diode may be on a micro-scale or a nano-scale. For example, the inorganic light-emitting diode may be a micro light-emitting diode. In another embodiment, the inorganic light-emitting diode may be a nanorod light-emitting diode, which may include gallium nitride (GaN). In another embodiment, a color converting layer may be disposed on the nanorod light-emitting diode and may include quantum dots. In still another embodiment, the light-emitting element may be a quantum dot light-emitting diode including a quantum dot emission layer.

In an embodiment and referring to FIG. 2A, the sealing structure may include a sealing substrate 400 and a sealing member 500, where the sealing substrate 400 may be disposed on the light-emitting element layer 300. In other words, the light-emitting element layer 300 may be arranged between the substrate 100 and the sealing substrate 400. The sealing substrate 400 may be a transparent member. In an embodiment, the sealing substrate 400 may include glass.

In an embodiment, the sealing member 500 may be arranged between the substrate 100 and the sealing substrate 400. In an embodiment, the sealing member 500 may be arranged between the inorganic insulating layer 200 and the sealing substrate 400. The sealing member 500 may surround the display area DA in a plan view. The sealing member 500 may overlap the peripheral area PA in a plan view. Accordingly, an internal space between the light-emitting element layer 300 and the sealing substrate 400 may be sealed, and a moisture absorbent and/or filler may be arranged in the internal space.

In an embodiment, the sealing member 500 may be a sealant. In another embodiment, the sealing member 500 may include a material that is cured by a laser beam. For example, the sealing member 500 may be frit. In particular, the sealing member 500 may include a urethane resin, an epoxy resin, an acrylic resin, which are organic sealants, or an inorganic sealant. In an embodiment, the sealing member 500 may include silicone. For example, urethane acrylate or the like may be used as the urethane resin. For example, butyl acrylate, ethyl hexyl acrylate, or the like may be used as the acrylic resin. In addition, the sealing member 500 may include a material that is cured by heat.

In an embodiment and referring to FIG. 2B, the sealing structure may include an encapsulation layer 600 which may include at least one inorganic encapsulation layer and at least one organic encapsulation layer. The at least one inorganic encapsulation layer and the at least one organic encapsulation layer may be alternately stacked. In an embodiment, the encapsulation layer 600 may include a first inorganic encapsulation layer 610, an organic encapsulation layer 620, and a second inorganic encapsulation layer 630, which are sequentially stacked. The first inorganic encapsulation layer 610 and the second inorganic encapsulation layer 630 may overlap each other in the peripheral area PA, where each of the first inorganic encapsulation layer 610 and the second inorganic encapsulation layer 630 may include an inorganic insulating material, such as silicon oxide, silicon nitride, silicon oxynitride, aluminum oxide, titanium oxide, tantalum oxide, hafnium oxide and/or zinc oxide, or the like. In an embodiment, the zinc oxide may include zinc oxide (ZnO) and/or zinc peroxide (ZnO₂).

In an embodiment, the organic encapsulation layer 620 may include a polymer-based material, where the polymer-based material may include an acrylic resin, an epoxy resin, polyimide, polyethylene, or the like. In an embodiment, the organic encapsulation layer 620 may include acrylate.

In another embodiment, the sealing structure may include the sealing substrate 400 and the sealing member 500 of FIG. 2A and the encapsulation layer 600 of FIG. 2B at the same time.

In an embodiment, a touch sensor layer may be disposed on the sealing structure and may obtain coordinate information according to an external input, for example, a touch event.

In an embodiment, an anti-reflection layer may be disposed on the touch sensor layer, where the anti-reflection layer may reduce reflectance of light incident toward the display apparatus 1. In an embodiment, the anti-reflection layer may include a retarder and/or a polarizer. The retarder may be a film type or a liquid-crystal coating type and may include λ/2 retarder and/or a λ/4 retarder. The polarizer may also be a film type or a liquid-crystal coating type. The film-type polarizer may include a stretch-type synthetic resin film, and the liquid-crystal-coating-type polarizer may include liquid crystals in a certain arrangement. The retarder and the polarizer may further include a protective film.

In another embodiment, the anti-reflection layer may include a black matrix and color filters, where the color filters may be arranged considering a color of light emitted by the light-emitting element of the display apparatus 1. Each of the color filters may include red, green, or blue pigments or dyes. Alternatively, each of the color filters may further include quantum dots in addition to the pigments or dyes stated above. In another embodiment, some of the color filters may not include the pigments or dyes stated above and may include scattering particles such as titanium oxide.

In another embodiment, the anti-reflection layer may include a destructive interference structure, where the destructive interference structure may include a first reflective layer and a second reflective layer, which are disposed on different layers. First reflected light and second reflected light reflected by the first reflective layer and the second reflective layer, respectively, may destructively interfere with each other, and accordingly, the reflectance of external light may be reduced.

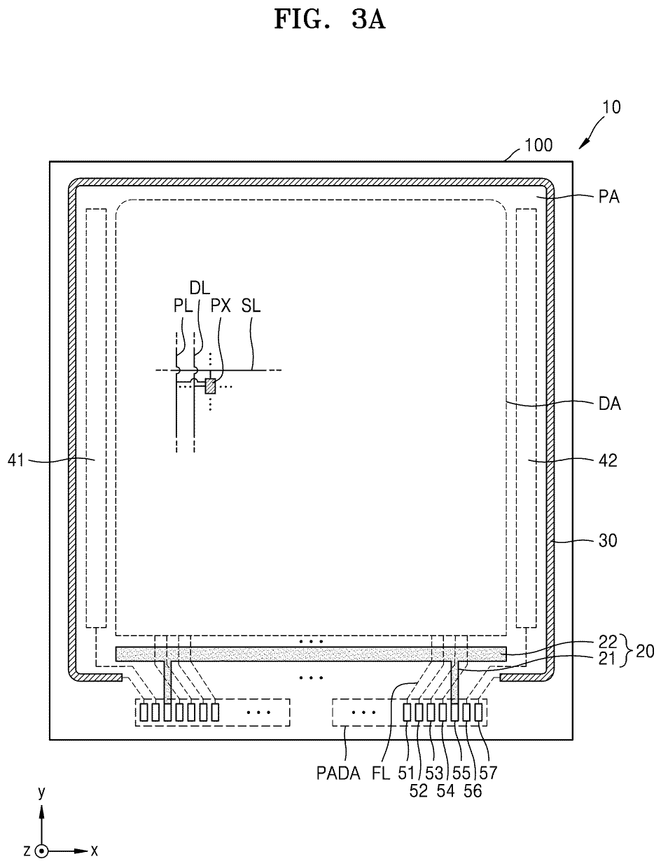

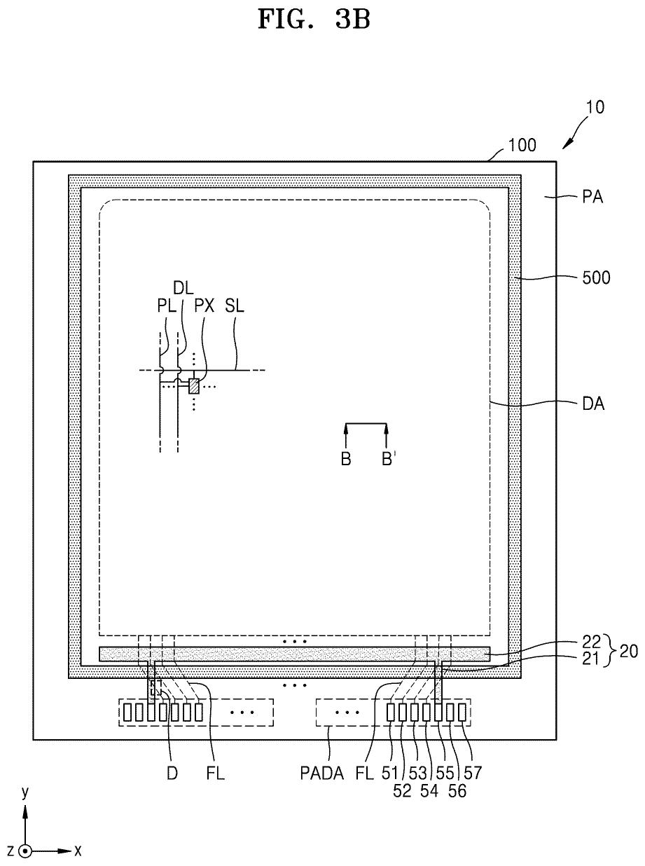

FIGS. 3A and 3B are plan views each schematically illustrating a display panel of a display apparatus, according to an embodiment. In FIG. 3B, some of the components shown in FIG. 3A are omitted, and the sealing member 500 surrounding the display area DA is shown. For example, in FIG. 3B, a second power voltage line and first and second scan driving units are omitted.

In an embodiment and referring to FIGS. 3A and 3B, the substrate 100 of the display panel 10 may include the display area DA and the peripheral area PA. A sub-pixel PX may be arranged in the display area DA. A plurality of sub-pixels PX may be included in the display area DA. Each sub-pixel PX may be implemented as a light-emitting element such as an organic light-emitting diode. Each sub-pixel PX may emit, for example, red, green, blue, or white light.

In an embodiment, a sub-pixel circuit driving the sub-pixel PX may be connected to a signal line or voltage line configured to control the turning on/off and brightness of the light-emitting element. For example, FIGS. 3A and 3B show a data line DL and a scan line SL as signal lines and a driving voltage line PL as a voltage line. The sub-pixel PX may be electrically connected to the data line DL. The scan line SL may extend in a first direction (e.g., an x direction). The data line DL may extend in a second direction (e.g., a y direction). In addition, the sub-pixel PX may be connected to the driving voltage line PL. In a plan view, the scan line SL, the data line DL, and the driving voltage line PL may overlap the display area DA.

In an embodiment, the peripheral area PA may be disposed adjacent to the display area DA, where the peripheral area PA may surround the display area DA. The sub-pixel PX may not be arranged in the peripheral area PA. The peripheral area PA may include a pad area PADA. The pad area PADA may be arranged outside the display area DA. In an embodiment, a plurality of pad areas PADA may be provided. In other words, the pad area PADA may include a plurality of pad areas PADA. In an embodiment, the pad areas PADA may be arranged to be directed in parallel with each other in the first direction (e.g., the x direction). FIGS. 3A and 3B show the plurality of pad areas PADA, but in another embodiment, the display apparatus 1 may include one pad area PADA. FIGS. 3A and 3B show that the pad area PADA is arranged outside the display area DA in a −y direction, but in another embodiment, the pad area PADA may be arranged outside the display area DA in a y direction, an −x direction, or an x direction.

In an embodiment, a plurality of pads 51, 52, 53, 54, 55, 56, and 57 may be arranged in the pad area PADA. The pad area PADA may be exposed without being covered by an insulating layer and may be electrically connected to a controller (not shown), such as a flexible printed circuit board, a driver integrated circuit (IC), or the like. The controller may change a plurality of image signals transmitted from the outside into a plurality of image data signals and transmit the image data signals to the display area DA through the pads of the pad area PADA. In addition, the controller may receive a vertical synchronization signal, a horizontal synchronization signal, and a clock signal and generate control signals for controlling the driving of scan driving units 41 and 42 to transmit the generated control signals to the scan driving units 41 and 42 through the pad 56 of the pad area PADA. The controller may transmit different voltages to a first power voltage line 20 and a second power voltage line 30 through the pad 55 and the pad 57 of the pad area PADA, respectively. In addition, fan-out lines FL may be configured to transmit various signals and/or voltages to the display area DA.

In an embodiment, the peripheral area PA may include outer circuits for driving the sub-pixels PX. For example, the first power voltage line 20, the second power voltage line 30, the first scan driving unit 41, the second scan driving unit 42, and the fan-out line FL may be arranged in the peripheral area PA.

In an embodiment, the first power voltage line 20 may be arranged between the pad area PADA and the display area DA, where the first power voltage line 20 may be arranged in the peripheral area PA to correspond to the lower end portion of the display area DA. In an embodiment, the first power voltage line 20 may include a first-1 power voltage line 21 extending in the second direction (e.g., the y direction) and a first-2 power voltage line 22 connected to the first-1 power voltage line 21 and extending in the first direction (e.g., the x direction). The first power voltage line 20 may be electrically connected to the driving voltage line PL arranged in the display area DA. In addition, the first power voltage line 20 may be electrically connected to the pad 55 of the pad area PADA.

In an embodiment, the second power voltage line 30 may transmit a different voltage from the first power voltage line 20 and may be arranged between the pad area PADA and the display area DA. The second power voltage line 30 may be arranged in the peripheral area PA to partially surround the display area DA. In an embodiment, the second power voltage line 30 may extend along the remaining sides of the display area DA except for any one side thereof, which is disposed adjacent to the first power voltage line 20. However, the invention is not limited thereto. In another embodiment, the second power voltage line 30 may be arranged to correspond to all sides of the display area DA. In another embodiment, various modifications are possible, for example, the second power voltage line 30 may be arranged to correspond to any one side or two sides of the display area DA. The second power voltage line 30 may be electrically connected to the pad 57 of the pad area PADA.

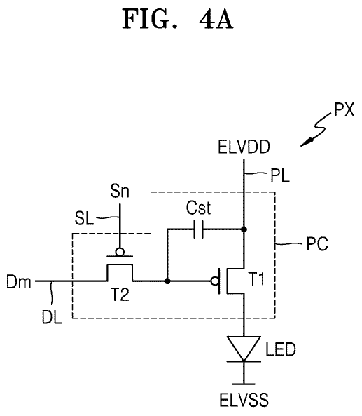

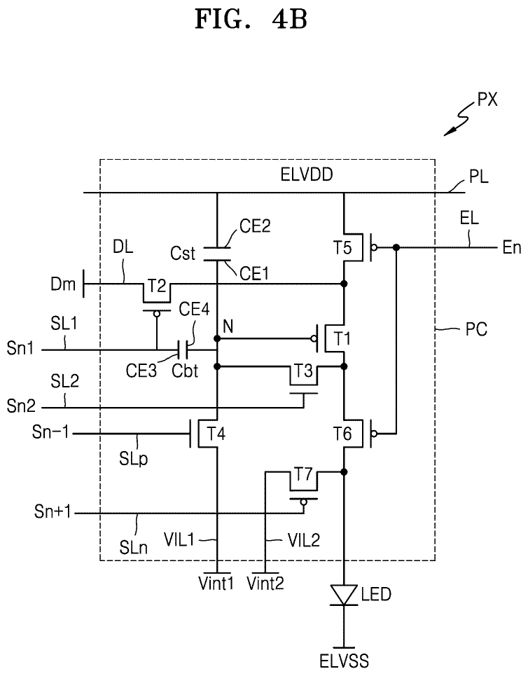

In an embodiment, the first power voltage line 20 may be configured to provide a driving voltage ELVDD (refer to FIG. 4A) to each sub-pixel PX, and the second power voltage line 30 may be configured to provide a common voltage ELVSS (refer to FIG. 4A) to each sub-pixel PX. For example, the driving voltage ELVDD may be provided to each sub-pixel PX through the driving voltage line PL electrically connected to the first power voltage line 20. The common voltage ELVSS may be connected to an opposite electrode of an organic light-emitting diode provided in each sub-pixel PX in the peripheral area PA.

In an embodiment, the first scan driving unit 41 may apply a scan signal to each sub-pixel PX through the scan line SL. The second scan driving unit 42 may be positioned on the opposite side of the first scan driving unit 41 with respect to the display area DA and may be directed substantially parallel to the first scan driving unit 41. Some of the sub-pixel circuits of the sub-pixels PX arranged in the display area DA may be electrically connected to the first scan driving unit 41, and the remaining sub-pixel circuits may be electrically connected to the second scan driving unit 42.

FIG. 3A shows an embodiment where the scan driving units 41 and 42 are respectively arranged on both sides of the display area DA, but the invention is not limited thereto. In another embodiment, the scan driving units 41 and 42 may be arranged only on one side of the display area DA, and when the scan driving units 41 and 42 are arranged in a printed circuit board or the like, various modifications are possible, for example, the scan driving units 41 and 42 may not be arranged in the peripheral area PA.

In an embodiment, the fan-out line FL may extend from the pad area PADA to the display area DA and may overlap the peripheral area PA in a plan view. In an embodiment, a plurality of fan-out lines FL may be provided. In an embodiment, the fan-out line FL may be a signal line. For example, the fan-out line FL may be electrically connected to the data line DL. In another embodiment, the fan-out line FL may be a voltage line. The fan-out line FL may be electrically connected to each of the pads 51, 52, 53, and 54 of the pad area PADA. The fan-out line FL may be configured to transmit an electrical signal and/or voltage received from the controller to the display area DA through the pad area PADA.

In an embodiment, in a plan view, the fan-out line FL may overlap at least a portion of the first power voltage line 20. For example, the fan-out line FL may overlap a portion of the first-1 power voltage line 21.

In an embodiment and referring to FIG. 3B, the sealing member 500 may be arranged in the peripheral area PA and may surround the display area DA in a plan view. The sealing member 500 may be arranged between the pad area PADA and the display area DA. In an embodiment, the fan-out line FL may extend across the sealing member 500 in a plan view.

The fan-out line FL and the first power voltage line 20 according to embodiments are described below in more detail.

FIG. 4A is an equivalent circuit diagram schematically illustrating a sub-pixel of a display panel, according to an embodiment.

In an embodiment and referring to FIG. 4A, the sub-pixel PX may include a sub-pixel circuit PC and a light-emitting element LED electrically connected to the sub-pixel circuit PC. The sub-pixel circuit PC may include a driving transistor T1, a switching transistor T2, and a first storage capacitor Cst. The sub-pixel PX may emit, for example, red, green, or blue light, or may emit red, green, blue, or white light through the light-emitting element LED.

In an embodiment, the switching transistor T2 may be connected to the scan line SL and the data line DL and be configured to transmit, to the driving transistor T1, a data voltage or a data signal Dm input to the data line DL, according to a scan voltage or a scan signal Sn input to the scan line SL.

In an embodiment, the first storage capacitor Cst may be connected to the switching transistor T2 and the driving voltage line PL, and store a voltage corresponding to the difference between a voltage received from the switching transistor T2 and the driving voltage ELVDD supplied to the driving voltage line PL.

In an embodiment, the driving transistor T1 may be connected to the driving voltage line PL and the first storage capacitor Cst, and may control a driving current flowing from the driving voltage line PL to the light-emitting element LED in accordance with a voltage value stored in the first storage capacitor Cst. The light-emitting element LED may emit light having a certain brightness according to the driving current. An opposite electrode (e.g., a cathode) of the light-emitting element LED may receive the common voltage ELVSS.

FIG. 4A shows that the sub-pixel circuit PC includes two transistors and one storage capacitor, but in another embodiment, the sub-pixel circuit PC may include three or more transistors.

FIG. 4B is an equivalent circuit diagram schematically illustrating a sub-pixel PX of a display panel, according to another embodiment.

In an embodiment and referring to FIG. 4B, the sub-pixel circuit PC may include a plurality of transistors T1 to T7, the first storage capacitor Cst, and a second storage capacitor Cbt. The plurality of transistors T1 to T7, the first storage capacitor Cst, and the second storage capacitor Cbt may be connected to signal lines SL1, SL2, SLp, SLn, EL, and DL, a first initialization voltage line VIL1, a second initialization voltage line VIL2, and the driving voltage line PL. In an embodiment, at least one of the signal lines, the first initialization voltage line VIL1, the second initialization voltage line VIL2 and/or the driving voltage line PL may be shared by neighboring sub-pixels PX.

In an embodiment, the plurality of transistors T1 to T7 may include a driving transistor T1, a switching transistor T2, a compensation transistor T3, a first initialization transistor T4, an operation control transistor T5, an emission control transistor T6, and a second initialization transistor T7. However, the invention is not limited thereto.

In an embodiment, the light-emitting element LED may include a sub-pixel electrode and an opposite electrode, where the sub-pixel electrode of the light-emitting element LED may be connected to the driving transistor T1 via the emission control transistor T6 to receive a driving current, and the opposite electrode may receive the common voltage ELVSS. The light-emitting element LED may emit light having a brightness corresponding to the driving current. In an embodiment, the light-emitting element LED may be an organic light-emitting diode including an organic emission layer.

In an embodiment, the driving voltage line PL may be configured to transmit the driving voltage ELVDD to the driving transistor T1. The first initialization voltage line VIL1 may be configured to transmit a first initialization voltage Vint1 for initializing the driving transistor T1 to the sub-pixel circuit PC. The second initialization voltage line VIL2 may be configured to transmit a second initialization voltage Vint2 for initializing the light-emitting element LED to the sub-pixel circuit PC.

In an embodiment, among the driving transistor T1, the switching transistor T2, the compensation transistor T3, the first initialization transistor T4, the operation control transistor T5, the emission control transistor T6, and the second initialization transistor T7, the compensation transistor T3 and the first initialization transistor T4 may be implemented as n-channel metal-oxide-semiconductor field-effect transistors (MOSFET) (NMOS), and the remaining transistors may be p-channel MOSFETs (PMOS).

In an embodiment, a drain area of the driving transistor T1 may be electrically connected to the light-emitting element LED via the emission control transistor T6. The driving transistor T1 may receive the data signal Dm in response to a switching operation of the switching transistor T2 and supply a driving current to the light-emitting element LED.

In an embodiment, the switching transistor T2 may be turned on in response to a first scan signal Sn1 received through a first scan line SL1 and may perform a switching operation of transmitting the data signal Dm transmitted through the data line DL to a source area of the driving transistor T1.

In an embodiment, a gate electrode of the compensation transistor T3 may be connected to a second scan line SL2. A source area of the compensation transistor T3 may be connected to the sub-pixel electrode of the light-emitting element LED via the emission control transistor T6 while being connected to the drain area of the driving transistor T1. A drain area of the compensation transistor T3 may be connected together to any one electrode of the first storage capacitor Cst, a source area of the first initialization transistor T4, and a gate electrode of the driving transistor T1. The compensation transistor T3 may be turned on in response to a second scan signal Sn2 received through the second scan line SL2 and connect the gate electrode of the driving transistor T1 to the drain area of the driving transistor T1 to diode-connect the driving transistor T1.

In an embodiment, a gate electrode of the first initialization transistor T4 may be connected to a previous scan line SLp. A drain area of the first initialization transistor T4 may be connected to the first initialization voltage line VIL1. A source area of the first initialization transistor T4 may be connected together to any one electrode of the first storage capacitor Cst, the drain area of the compensation transistor T3, and the gate electrode of the driving transistor T1. The first initialization transistor T4 may be turned on in response to a previous scan signal Sn−1 received through the previous scan line SLp and configured to transmit the first initialization voltage Vint1 to the gate electrode of the driving transistor T1 to perform an initialization operation of initializing a voltage of the gate electrode of the driving transistor T1.

In an embodiment, a gate electrode of the second initialization transistor T7 may be connected to a following scan line SLn. A source area of the second initialization transistor T7 may be connected to the sub-pixel electrode of the light-emitting element LED. A drain area of the second initialization transistor T7 may be connected to the second initialization voltage line VIL2. The second initialization transistor T7 may be turned on in response to a following scan signal Sn+1 received through the following scan line SLn to initialize the sub-pixel electrode of the light-emitting element LED.

In an embodiment, the first storage capacitor Cst may include a first capacitor electrode CE1 and a second capacitor electrode CE2. The first capacitor electrode CE1 may be connected to the gate electrode of the driving transistor T1, and the second capacitor electrode CE2 may be connected to the driving voltage line PL. The first storage capacitor Cst may maintain a voltage applied to the gate electrode of the driving transistor T1 by storing and maintaining a voltage corresponding to the difference between voltages of both ends of the driving voltage line PL and the gate electrode of the driving transistor T1.

In an embodiment, the second storage capacitor Cbt may include a third capacitor electrode CE3 and a fourth capacitor electrode CE4. The third capacitor electrode CE3 may be connected to the first scan line SL1 and a gate electrode of the switching transistor T2. The fourth capacitor electrode CE4 may be connected to the gate electrode of the driving transistor T1 and the first capacitor electrode CE1 of the first storage capacitor Cst. The second storage capacitor Cbt is a boosting capacitor, and when the first scan signal Sn1 of the first scan line SL1 is a voltage that turns off the switching transistor T2, the second storage capacitor Cbt may increase a voltage of a node N to reduce a voltage (black voltage) that displays black.

A detailed operation of each sub-pixel circuit PC, according to an embodiment is as follows.

In an embodiment, during a first initialization period, when the previous scan signal Sn−1 is supplied through the previous scan line SLp, the first initialization transistor T4 may be turned on in response to the previous scan signal Sn−1, and the driving transistor T1 may be initialized by the first initialization voltage Vint1 supplied from the first initialization voltage line VIL1.

In an embodiment, during a data programming period, when the first scan signal Sn1 and the second scan signal Sn2 are supplied through the first scan line SL1 and the second scan line SL2, respectively, the switching transistor T2 and the compensation transistor T3 may be turned on in response to the first scan signal Sn1 and the second scan signal Sn2. At this time, the driving transistor T1 may be diode-connected by the compensation transistor T3 which is turned on and which may be biased in a forward direction. Then, a compensation voltage obtained by compensating a threshold voltage of the driving transistor T1 is from the data signal Dm supplied from the data line DL which may be applied to the gate electrode of the driving transistor T1. The driving voltage ELVDD and the compensation voltage may be applied to both ends of the first storage capacitor Cst, and a charge corresponding to a voltage difference between both ends of the first storage capacitor Cst may be stored in the first storage capacitor Cst.

In an embodiment, during an emission period, the operation control transistor T5 and the emission control transistor T6 may be turned on by an emission control signal En supplied from an emission control line EL. A driving current may be generated according to a voltage difference between a voltage of the gate electrode of the driving transistor T1 and the driving voltage ELVDD, and the driving current may be supplied to the light-emitting element LED through the emission control transistor T6.

In an embodiment, during a second initialization period, when the following scan signal Sn+1 is supplied through the following scan line SLn, the second initialization transistor T7 may be turned on in response to the following scan signal Sn+1, and the light-emitting element LED may be initialized by the second initialization voltage Vint2 supplied from the second initialization voltage line VIL2.

In an embodiment, at least one of the plurality of transistors T1 to T7 may be provided as an oxide-based transistor including an oxide semiconductor, and the remaining transistors may be provided as silicon-based transistors including silicon semiconductors.

In particular, in an embodiment, the driving transistor T1, which directly affects the brightness of a display apparatus, may be configured to include a semiconductor layer including highly reliable polycrystalline silicon, and accordingly, a display apparatus with high resolution may be implemented.

Because an oxide semiconductor has high carrier mobility and low leakage current, a voltage drop may not be large even when a driving time is long. That is, because color change of an image according to a voltage drop is not large even during low-frequency driving, the low-frequency driving is possible.

As such, in an embodiment, as an oxide semiconductor has low leakage current, at least one of the compensation transistor T3, the first initialization transistor T4, and the second initialization transistor T7, which is connected to the gate electrode of the driving transistor T1, may include an oxide semiconductor, thereby preventing leakage current that may flow to the gate electrode of the driving transistor T1 and reducing power consumption.

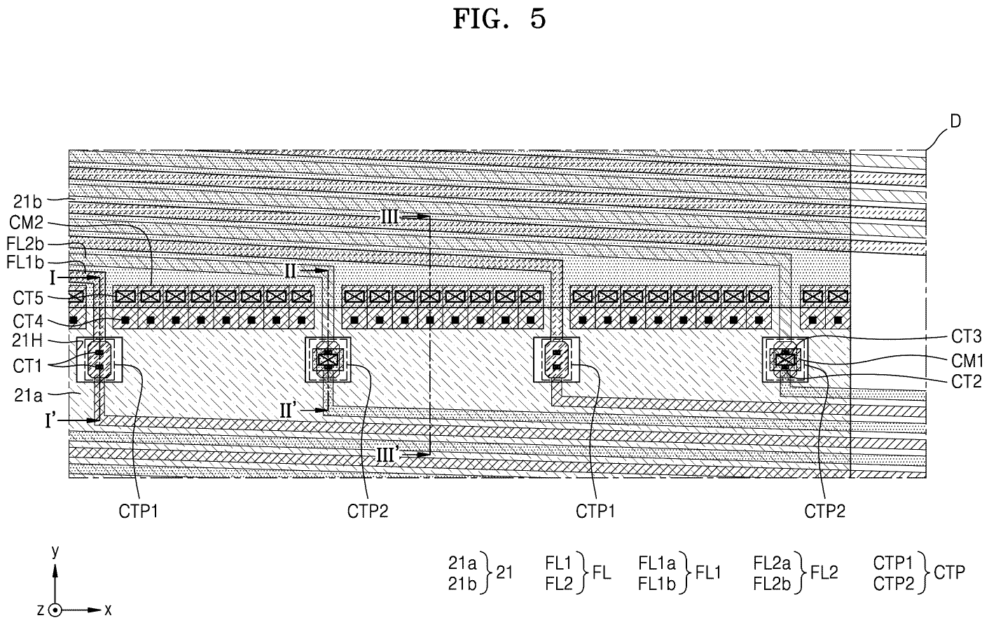

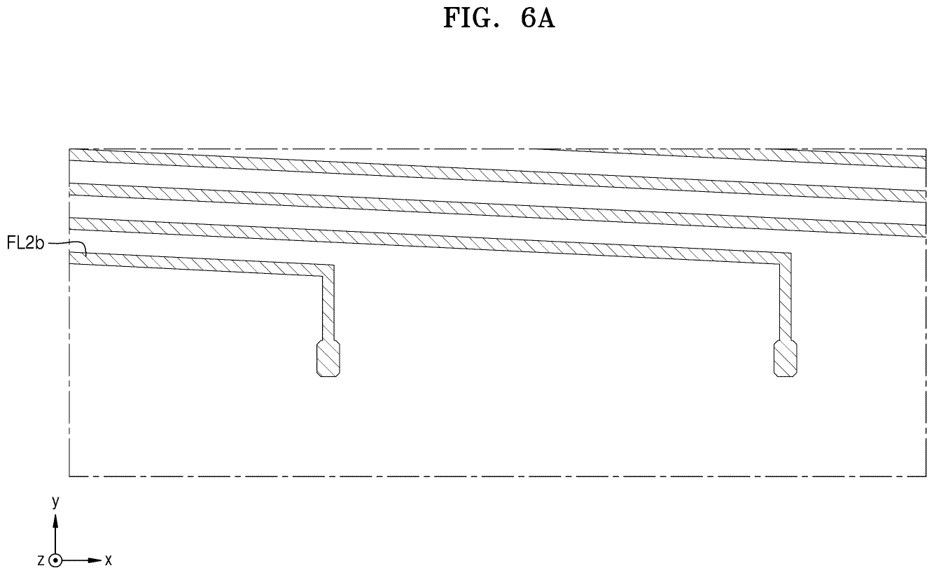

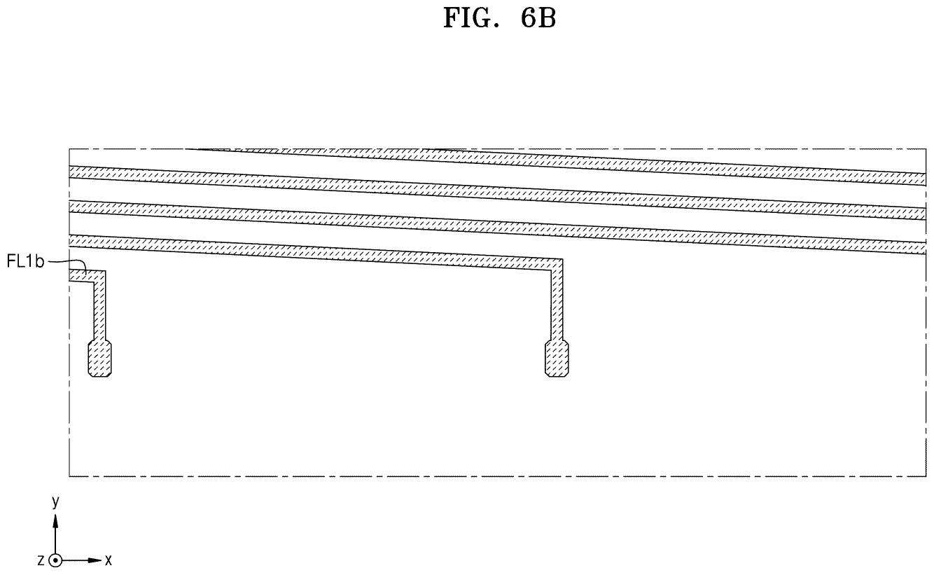

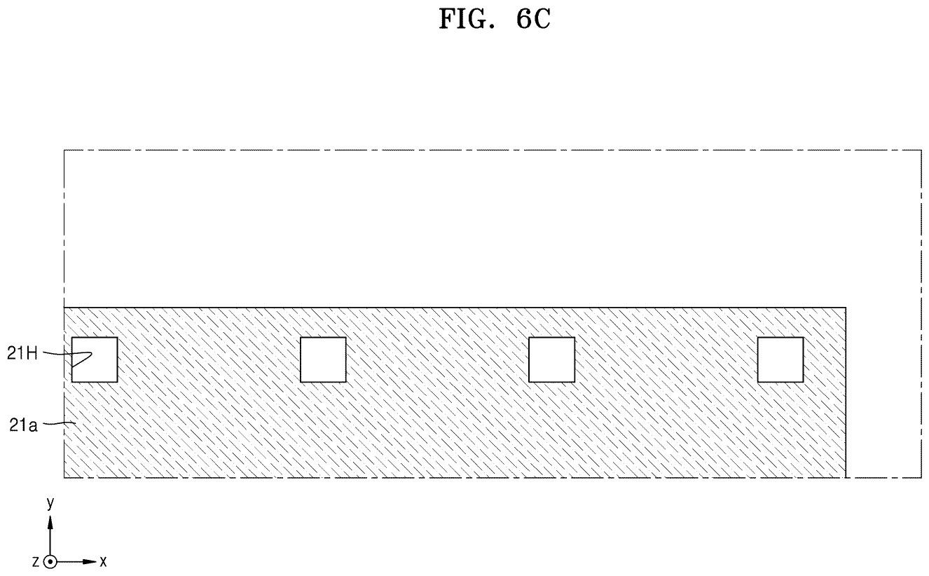

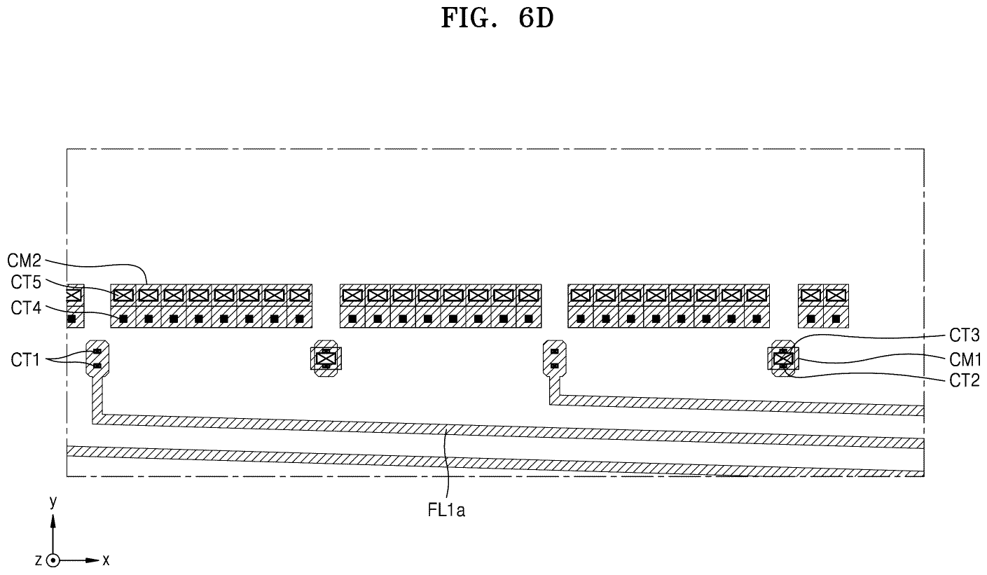

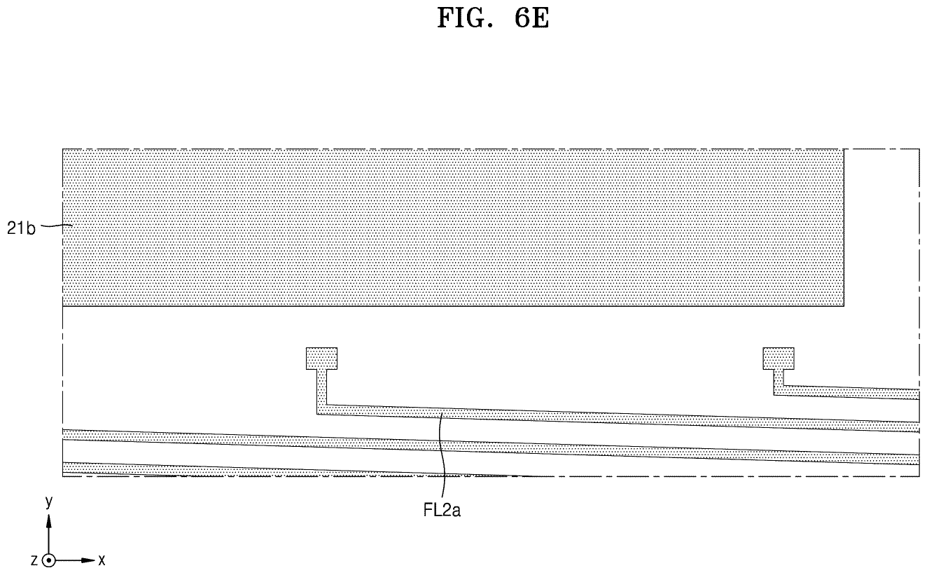

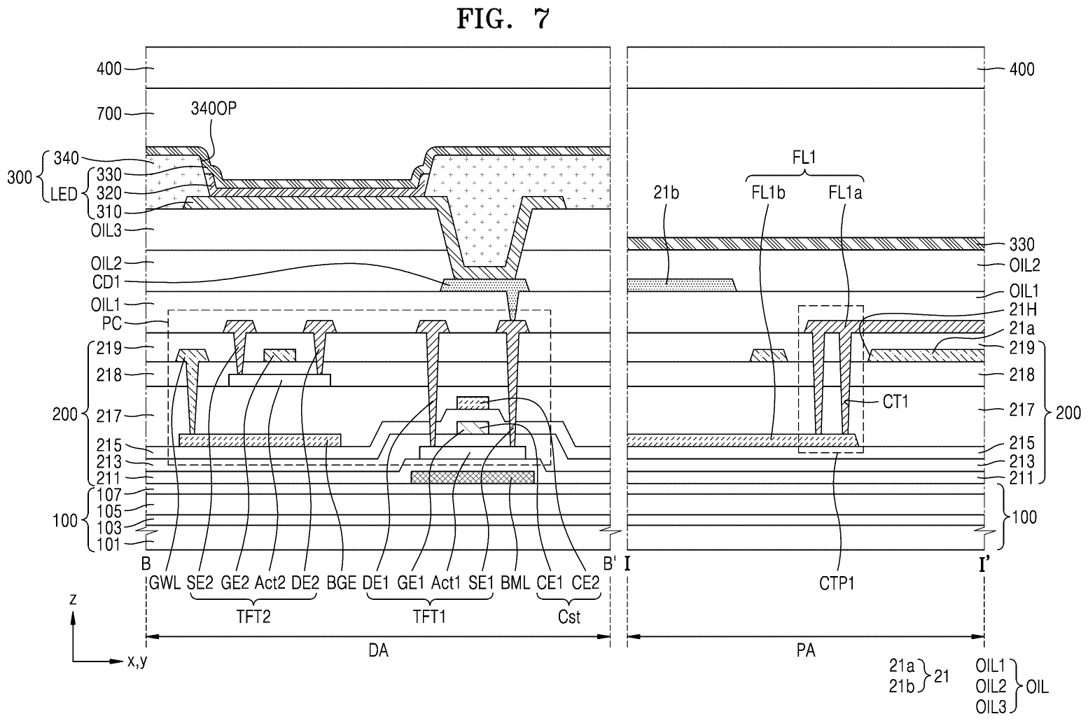

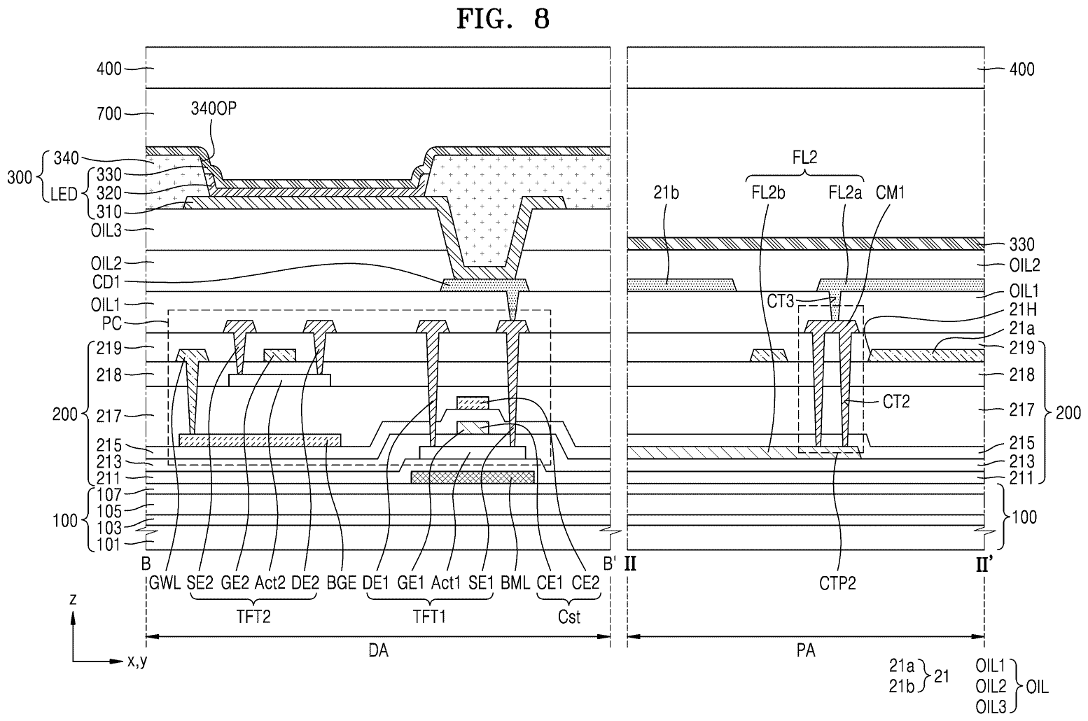

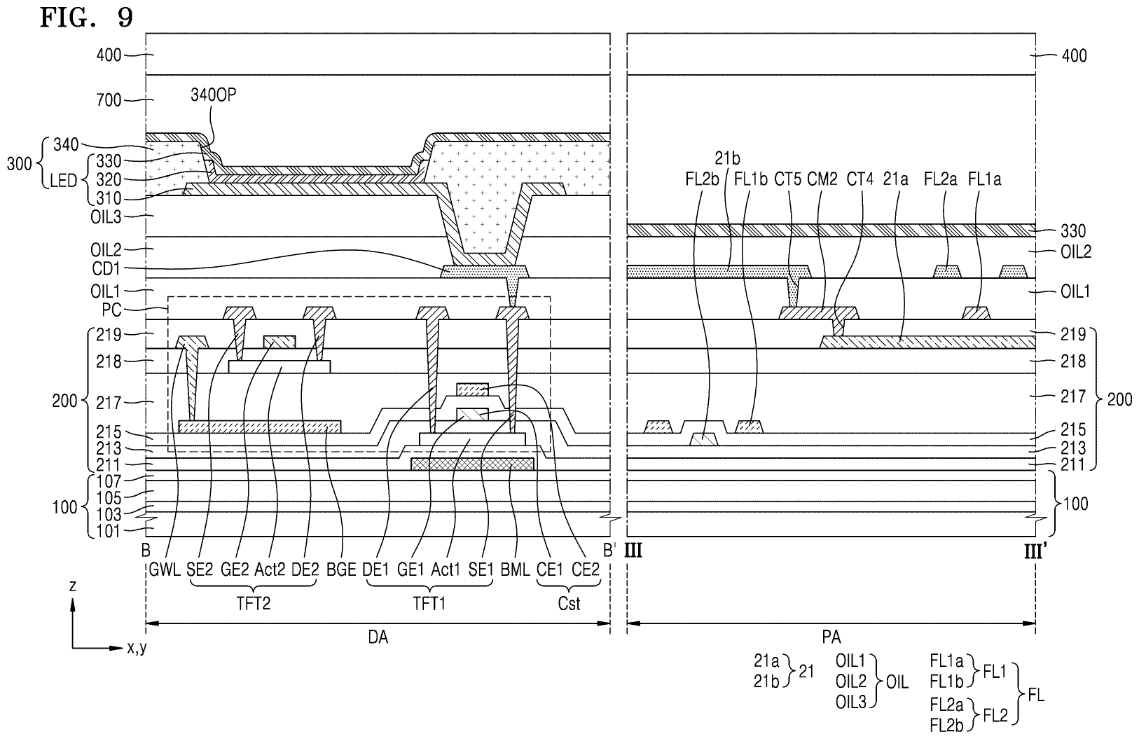

FIG. 5 is an enlarged plan view of a region D of FIG. 3B, which is a portion of a display panel, according to an embodiment. In addition, FIGS. 6A to 6E are plan views each illustrating a portion of the display panel shown in FIG. 5, according to an embodiment. FIG. 7 is a diagram schematically illustrating a cross-section view taken along a line B-B′ of FIG. 3B and a line I-I′ of FIG. 5, according to an embodiment. FIG. 8 is a diagram schematically illustrating a cross-section taken along the line B-B′ of FIG. 3B and a line II-II′ of FIG. 5, according to an embodiment, and FIG. 9 is a diagram schematically illustrating a cross-section taken along the line B-B′ of FIG. 3B and a line III-III′ of FIG. 5, according to an embodiment.

First, a stacked structure of components included in a display apparatus is described mainly focusing on the display area DA with reference to FIG. 7.

In an embodiment, in the display area DA, the display panel 10 may include the substrate 100, the inorganic insulating layer 200, the sub-pixel circuit PC, an organic insulating layer OIL, the light-emitting element layer 300, the sealing substrate 400 as a sealing structure, and a filling layer 700.

In an embodiment, the substrate 100 includes the display area DA and the peripheral area PA and may include a glass material or a polymer resin. In an embodiment, the substrate 100 may have an alternating stacked structure of a base layer including a polymer resin and a barrier layer including an inorganic insulating material, such as silicon oxide or silicon nitride. For example, the substrate 100 may include a first base layer 101, a first barrier layer 103, a second base layer 105, and a second barrier layer 107, which are sequentially stacked. Each of the first base layer 101 and the second base layer 105 may include a polymer resin, and each of the first barrier layer 103 and the second barrier layer 107 may include an inorganic insulating material.

In an embodiment, the inorganic insulating layer 200 may be disposed on the substrate 100 and may overlap the display area DA and the peripheral area PA. In an embodiment, the inorganic insulating layer 200 may include a buffer layer 211, a first inorganic insulating layer 213, a second inorganic insulating layer 215, a third inorganic insulating layer 217, a fourth inorganic insulating layer 218, and a fifth inorganic insulating layer 219. The buffer layer 211, the first inorganic insulating layer 213, the second inorganic insulating layer 215, the third inorganic insulating layer 217, the fourth inorganic insulating layer 218, and the fifth inorganic insulating layer 219 may be sequentially stacked on the substrate 100.

In an embodiment, the sub-pixel circuit PC may include at least one transistor and at least one capacitor. In an embodiment, the sub-pixel circuit PC may include a first transistor TFT1, a second transistor TFT2, and a first storage capacitor Cst. The first transistor TFT1 may include a first semiconductor layer Act1, a first gate electrode GE1, a first source electrode SE1, and a first drain electrode DE1. The second transistor TFT2 may include a second semiconductor layer Act2, a second gate electrode GE2, a second source electrode SE2, and a second drain electrode DE2. The first storage capacitor Cst may include a first capacitor electrode CE1 and a second capacitor electrode CE2.

In an embodiment, the buffer layer 211 may be disposed on the substrate 100. The buffer layer 211 may include an inorganic insulating material, such as silicon nitride, silicon oxynitride, and silicon oxide, and may include a single layer or a multi-layer, each including the inorganic insulating material stated above.

In an embodiment, a lower metal layer BML may be arranged between the substrate 100 and the buffer layer 211. The lower metal layer BML may overlap at least one of the first semiconductor layer Act1 and the second semiconductor layer Act2 in a plan view. In some embodiments, an electrostatic voltage or a signal may be applied to the lower metal layer BML. The lower metal layer BML may include a conductive material including molybdenum (Mo), aluminum (Al), copper (Cu), titanium (Ti), or the like, and may include a multi-layer or a single layer, each including the above material. Because the lower metal layer BML overlaps at least one of the first semiconductor layer Act1 and the second semiconductor layer Act2 in a plan view, the characteristics of at least one of the first transistor TFT1 and the second transistor TFT2 may be improved.

In an embodiment, at least one of the first semiconductor layer Act1 and the second semiconductor layer Act2 may include an oxide semiconductor. In an embodiment, the first semiconductor layer Act1 may include a silicon semiconductor, and the second semiconductor layer Act2 may include an oxide semiconductor. Each of the first semiconductor layer Act1 and the second semiconductor layer Act2 may include a channel area, a source area, and a drain area, wherein the source area and the drain area are respectively arranged on both sides of the channel area.

The first semiconductor layer Act1 may be arranged between the buffer layer 211 and the first inorganic insulating layer 213. In an embodiment, the first semiconductor layer Act1 may include a silicon semiconductor. For example, the first semiconductor layer Act1 may include polysilicon or amorphous silicon.

The first inorganic insulating layer 213 may be disposed on the buffer layer 211 and the first semiconductor layer Act1. In an embodiment, the first inorganic insulating layer 213 may be a first gate insulating layer. The first inorganic insulating layer 213 may include an inorganic insulating material, such as silicon oxide, silicon nitride, silicon oxynitride, aluminum oxide, titanium oxide, tantalum oxide, hafnium oxide, zinc oxide, or the like.

In an embodiment, the first gate electrode GE1 may be arranged between the first inorganic insulating layer 213 and the second inorganic insulating layer 215. The first capacitor electrode CE1 may be arranged between the first inorganic insulating layer 213 and the second inorganic insulating layer 215. The first gate electrode GE1 may overlap the first semiconductor layer Act1. In an embodiment, the first gate electrode GE1 may overlap the channel area of the first semiconductor layer Act1.

In an embodiment, the first capacitor electrode CE1 and the first gate electrode GE1 may be an integral body. However, the invention is not limited thereto, and in another embodiment, the first capacitor electrode CE1 and the first gate electrode GE1 may be spaced apart from each other.

In an embodiment, the first gate electrode GE1 and the first capacitor electrode CE1 may be disposed on the same layer and may include the same material. Each of the first gate electrode GE1, the second gate electrode GE2, and the first capacitor electrode CE1 may include a conductive material including Mo, Al, Cu, Ti, or the like, and may include a multi-layer or a single layer, each including the above material.

In an embodiment, the second inorganic insulating layer 215 may be disposed on the first gate electrode GE1, the first capacitor electrode CE1, and the first inorganic insulating layer 213. In an embodiment, the second inorganic insulating layer 215 may be a second gate insulating layer and may include an inorganic insulating material, such as silicon oxide, silicon nitride, silicon oxynitride, aluminum oxide, titanium oxide, tantalum oxide, hafnium oxide, zinc oxide, or the like.

In an embodiment, the second capacitor electrode CE2 may be disposed on the second inorganic insulating layer 215 and may overlap the first gate electrode GE1 therebelow. The second capacitor electrode CE2 and the first gate electrode GE1 may overlap each other with the second inorganic insulating layer 215 therebetween to form the first storage capacitor Cst.

In an embodiment, the second capacitor electrode CE2 may be disposed on the second inorganic insulating layer 215 and may overlap the first capacitor electrode CE1 in a plan view. The first capacitor electrode CE1 and the second capacitor electrode CE2 may form the first storage capacitor Cst. The second capacitor electrode CE2 may include a conductive material including Mo, Al, Cu, Ti, or the like, and may include a multi-layer or a single layer, each including the above material.

In an embodiment, the third inorganic insulating layer 217 may be disposed on the second capacitor electrode CE2 and the second inorganic insulating layer 215. In an embodiment, the third inorganic insulating layer 217 may be a first interlayer insulating layer. The third inorganic insulating layer 217 may include an inorganic insulating material, such as silicon oxide, silicon nitride, silicon oxynitride, aluminum oxide, titanium oxide, tantalum oxide, hafnium oxide, zinc oxide, or the like.

In an embodiment, the second semiconductor layer Act2 may be disposed on the third inorganic insulating layer 217. In an embodiment, the second semiconductor layer Act2 may include an oxide semiconductor. For example, the second semiconductor layer Act2 may include a zinc-oxide-based material, and may include Zn oxide, In—Zn oxide, Ga—In—Zn oxide, or the like. In another embodiment, the second semiconductor layer Act2 may include an In—Ga—Zn—O (IGZO), In—Sn—Zn—O (ITZO), or In—Ga—Sn—Zn—O (IGTZO) semiconductor, which includes a metal such as indium (In), gallium (Ga), and tin (Sn) in ZnO.

In an embodiment, the fourth inorganic insulating layer 218 may be disposed on the second semiconductor layer Act2 and the third inorganic insulating layer 217. In an embodiment, the fourth inorganic insulating layer 218 may be a third gate insulating layer. In an embodiment, the fourth inorganic insulating layer 218 may include an inorganic insulating material, such as silicon oxide, silicon nitride, silicon oxynitride, aluminum oxide, titanium oxide, tantalum oxide, hafnium oxide, zinc oxide, or the like.

In an embodiment, the second gate electrode GE2 may be disposed on the fourth inorganic insulating layer 218 and may be arranged between the fourth inorganic insulating layer 218 and the fifth inorganic insulating layer 219. The second gate electrode GE2 may include a conductive material including Mo, Al, Cu, Ti, or the like, and may include a multi-layer or a single layer, each including the above material.

In an embodiment, the first source electrode SE1, the first drain electrode DE1, the second source electrode SE2, and the second drain electrode DE2 may be disposed on the fifth inorganic insulating layer 219. In an embodiment, the fifth inorganic insulating layer 219 may be a second interlayer insulating layer. In an embodiment, the fifth inorganic insulating layer 219 may include an inorganic insulating material, such as silicon oxide, silicon nitride, silicon oxynitride, aluminum oxide, titanium oxide, tantalum oxide, hafnium oxide, zinc oxide, or the like. The first source electrode SE1 and the first drain electrode DE1 may be connected to the first semiconductor layer Act1 through contact holes of insulating layers. The second source electrode SE2 and the second drain electrode DE2 may be electrically connected to the second semiconductor layer Act2 through contact holes of the insulating layers.

In an embodiment, the first source electrode SE1, the first drain electrode DE1, the second source electrode SE2, and the second drain electrode DE2 may be disposed on the same layer and may include the same material. Each of the first source electrode SE1, the first drain electrode DE1, the second source electrode SE2, and the second drain electrode DE2 may include a conductive material including Mo, Al, Cu, Ti, or the like, and may include a multi-layer or a single layer, each including the above material. In an embodiment, each of the first source electrode SE1, the first drain electrode DE1, the second source electrode SE2, and the second drain electrode DE2 may have a multi-layered structure of Ti/Al/Ti.

In an embodiment, a lower gate electrode BGE may be disposed on the lower portion of the second semiconductor layer Act2. In an embodiment, the lower gate electrode BGE may be arranged between the second inorganic insulating layer 215 and the third inorganic insulating layer 217. In an embodiment, the lower gate electrode BGE may receive a gate signal. In this case, the second transistor TFT2 may have a double gate electrode structure in which gate electrodes are disposed on the upper portion and the lower portion of the second semiconductor layer Act2. The lower gate electrode BGE and the second capacitor electrode CE2 may be disposed on the same layer and include the same material.

In an embodiment, a gate line GWL may be arranged between the fourth inorganic insulating layer 218 and the fifth inorganic insulating layer 219. In an embodiment, the gate line GWL may be electrically connected to the lower gate electrode BGE through contact holes provided in the insulating layers. The gate line GWL and the second gate electrode GE2 may be disposed on the same layer and include the same material. The gate line GWL and the second gate electrode GE2 may be an integral body.

In an embodiment, the organic insulating layer OIL may be disposed on the inorganic insulating layer 200, the first source electrode SE1, the first drain electrode DE1, the second source electrode SE2, and the second drain electrode DE2. In an embodiment, the organic insulating layer OIL may include a first organic insulating layer OIL1, a second organic insulating layer OIL2, and a third organic insulating layer OIL3. The organic insulating layer OIL may include an organic material. Each of the first organic insulating layer OIL1, the second organic insulating layer OIL2, and the third organic insulating layer OIL3 may include a general commercial polymer such as poly(methyl methacrylate) (PMMA) or polystyrene (PS), a polymer derivative having a phenol group, and an organic insulating material, such as an acrylic polymer, an imide polymer, an aryl ether polymer, an amide polymer, a fluorine polymer, a p-xylene polymer, a vinyl alcohol polymer, and a mixture thereof.

In an embodiment, a first connection electrode CD1 may be disposed on the first organic insulating layer OIL1. At this time, the first connection electrode CD1 may be connected to the first drain electrode DE1 or the first source electrode SE1 through a contact hole of the first organic insulating layer OIL1. The first connection electrode CD1 may include a conductive material including Mo, Al, Cu, Ti, or the like, and may include a multi-layer or a single layer, each including the above material. The second organic insulating layer OIL2 and the third organic insulating layer OIL3 may be arranged to cover the first connection electrode CD1.

In an embodiment, the light-emitting element layer 300 may be disposed on the organic insulating layer OIL. The light-emitting element layer 300 may include the light-emitting element LED and a bank layer 340. The light-emitting element LED may include a sub-pixel electrode 310, an emission layer 320, and an opposite electrode 330. The light-emitting element LED may be electrically connected to the sub-pixel circuit PC through a contact hole of the organic insulating layer OIL. In an embodiment, the sub-pixel electrode 310 of the light-emitting element LED may be electrically connected to the first connection electrode CD1 through the contact hole of the organic insulating layer OIL.

In an embodiment, the sub-pixel electrode 310 may be disposed on the organic insulating layer OIL and may be electrically connected to the sub-pixel circuit PC. In an embodiment, the organic insulating layer OIL may include a contact hole. The sub-pixel electrode 310 may be electrically connected to the sub-pixel circuit PC through the contact hole of the organic insulating layer OIL. In an embodiment, the sub-pixel electrode 310 may be electrically connected to the first source electrode SE1 or the first drain electrode DE1. The sub-pixel electrode 310 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the sub-pixel electrode 310 may include a reflective film including silver (Ag), magnesium (Mg), Al, platinum (Pt) palladium (Pd), gold (Au), nickel (Ni), neodymium (Nd), iridium (Ir), chromium (Cr), or compounds thereof. In still another embodiment, the sub-pixel electrode 310 may further include a film including ITO, IZO, ZnO, or In₂O₃ above/below the reflective film described above.

In an embodiment, the bank layer 340 including an opening portion 340OP exposing the central portion of the sub-pixel electrode 310 may be disposed on the sub-pixel electrode 310. The bank layer 340 may include an organic insulating material and/or an inorganic insulating material. In some embodiments, the bank layer 340 may include a light-blocking material. The opening portion 340OP of the bank layer 340 may define an emission area of light emitted by the light-emitting element LED.

In an embodiment, the bank layer 340 may further include a spacer (not shown) protruding in a thickness direction of the substrate 100. The spacer may protrude from the bank layer 340 in a third direction (e.g., a z direction). The bank layer 340 including the spacer may be formed by using a halftone mask. In some embodiments, the spacer may include a different material from the bank layer 340 and may be disposed on the bank layer 340.

In an embodiment, the emission layer 320 may be arranged in the opening portion 340OP of the bank layer 340. The emission layer 320 may include a polymer organic material or a low-molecular-weight organic material, which emits light of a color. Although not illustrated in FIG. 7, a first functional layer and a second functional layer may be respectively disposed below and above the emission layer 320. The first functional layer may include, for example, a hole transport layer (HTL) or may include an HTL and a hole injection layer (HIL). The second functional layer, as a component disposed above the emission layer 320, is optional. The second functional layer may include an electron transport layer (ETL) and/or an electron injection layer (EIL). Similar to the opposite electrode 330 to be described below, the first functional layer and/or the second functional layer may be a common layer entirely covering the substrate 100.

In an embodiment, the opposite electrode 330 may be disposed on the emission layer 320 and may include a conductive material having a low work function. For example, the opposite electrode 330 may include a (semi) transparent layer including Ag, Mg, Al, Pt, Pd, Au, Ni, Nd, Ir, Cr, lithium (Li), calcium (Ca), alloys thereof, or the like. In another embodiment, the opposite electrode 330 may further include a layer such as ITO, IZO, ZnO, or In₂O₃ above the (semi) transparent layer including the above-stated material.

In an embodiment, the sealing substrate 400 may be disposed on the light-emitting element LED. In the display area DA, the filling layer 700 may be arranged between the light-emitting element LED and the sealing substrate 400. The filling layer 700 may include a filler.

In an embodiment and referring to FIG. 5, the display panel may include the fan-out line FL and the first-1 power voltage line 21 of the first power voltage line 20 (refer to FIG. 3B).

In an embodiment, the fan-out line FL may be arranged in the peripheral area PA and may extend from the pad area PADA (refer to FIG. 3B) to the display area DA (refer to FIG. 3B). In an embodiment, the fan-out line FL may extend in the second direction (e.g., the y direction). In another embodiment, the fan-out line FL may extend in a direction intersecting the first direction (e.g., the x direction) and the second direction (e.g., the y direction). A plurality of fan-out lines FL may be provided. In an embodiment, FIG. 5 shows four fan-out lines FL each including a contact portion CTP, but four or more fan-out lines FL may be provided.

In an embodiment, the first power voltage line 20 may be arranged in the peripheral area PA. The first power voltage line 20 may be arranged between the pad area PADA (refer to FIG. 3B) and the display area DA (refer to FIG. 3B). The first-1 power voltage line 21 of the first power voltage line 20 may extend in the second direction (e.g., the y direction). In an embodiment, each of the fan-out lines FL may overlap at least a portion of the first power voltage line 20. In an embodiment, a width of the first power voltage line 20 in the first direction (e.g., the x direction) may be greater than a width of one fan-out line FL in the first direction (e.g., the x direction).

Hereinafter, the structure of the first-1 power voltage line 21 and the fan-out line FL are described on the assumption that the first power voltage line 20, for example, the first-1 power voltage line 21, overlaps the fan-out line FL, but the same description may also be applied to the structure of the second power voltage line 30 and the fan-out line FL when the second power voltage line 30 (refer to FIG. 3A) overlaps the fan-out line FL.

In an embodiment, the fan-out line FL may include first fan-out lines FL1 and second fan-out lines FL2, where the second fan-out line FL2 may be arranged alternately with an adjacent first fan-out line FL1 in a plan view. For example, the second fan-out line FL2 may be arranged to be disposed between adjacent first fan-out lines FL1 in a plan view. In other words, the first fan-out line FL1 may be arranged between adjacent second fan-out lines FL2 in a plan view. In an embodiment, the second fan-out line FL2 may have a different line structure from the first fan-out line FL1, for example, the second fan-out line FL2 is disposed on a different layer from the first fan-out line FL1 or includes a different material from the first fan-out line FL1. However, the invention is not limited thereto. In another embodiment, the fan-out line FL may include only the first fan-out lines FL1 or the second fan-out lines FL2. Hereinafter, description is made on the assumption that the fan-out line FL includes the first fan-out lines FL1 and the second fan-out lines FL2.

In an embodiment, the fan-out line FL may include a first sub-line and a second sub-line. In a plan view of the fan-out line FL, the first sub-line may be arranged closer to the pad area PADA than the second sub-line, and the second sub-line may be arranged closer to the display area DA than the first sub-line. For example, the first fan-out line FL1 may include a first-1 sub-line FL1a and a first-2 sub-line FL1b. In a plan view, the first-1 sub-line FL1a of the first fan-out line FL1 may be arranged closer to the pad area PADA than the first-2 sub-line FL1b. In addition, the second fan-out line FL2 may include a second-1 sub-line FL2a and a second-2 sub-line FL2b. In a plan view, the second-1 sub-line FL2a of the second fan-out line FL2 may be arranged closer to the pad area PADA than the second-2 sub-line FL2b.

In an embodiment, the first sub-line and the second sub-line of the fan-out line FL may be disposed on different layers. The first sub-line of the fan-out line FL may be disposed on the inorganic insulating layer 200, and the second sub-line of the fan-out line FL may be inserted into the inorganic insulating layer 200. For example, the first sub-line of the fan-out line FL may be arranged between the inorganic insulating layer 200 and the first organic insulating layer OIL1 or between the first organic insulating layer OIL1 and the second organic insulating layer OIL2. The second sub-line of the fan-out line FL may be arranged between the first inorganic insulating layer 213 and the second inorganic insulating layer 215 or between the second inorganic insulating layer 215 and the third inorganic insulating layer 217. The second sub-line of the fan-out line FL may be electrically connected to the first sub-line in the contact portion CTP.

In an embodiment and referring to FIGS. 5, 6B, 6D, and 7, the first-1 sub-line FL1a and the first-2 sub-line FL1b of the first fan-out line FL1 may be disposed on different layers. The first-1 sub-line FL1a of the first fan-out line FL1 may be arranged between the fifth inorganic insulating layer 219 and the first organic insulating layer OIL1. The first-1 sub-line FL1a may be disposed on the same layer as the first source electrode SE1, the first drain electrode DE1, the second source electrode SE2, and the second drain electrode DE2, which are arranged in the display area DA, and may include the same material as the first source electrode SE1, the first drain electrode DE1, the second source electrode SE2, and the second drain electrode DE2. The first-2 sub-line FL1b may be arranged between the second inorganic insulating layer 215 and the third inorganic insulating layer 217. The first-2 sub-line FL1b may be disposed on the same layer as the second capacitor electrode CE2 of the first storage capacitor Cst in the display area DA and may include the same material as the second capacitor electrode CE2.

In an embodiment and in a plan view, the first-1 sub-line FL1a and the first-2 sub-line FL1b of the first fan-out line FL1 may be electrically connected to each other in a first contact portion CTP1. The first-2 sub-line FL1b of the first fan-out line FL1 may be connected to the first-1 sub-line FL1a through a contact hole CT1 of the first contact portion CTP1.

In an embodiment and referring to FIGS. 5, 6A, 6E, and 8, the second-1 sub-line FL2a and the second-2 sub-line FL2b of the second fan-out line FL2 may be disposed on different layers. The second-1 sub-line FL2a of the second fan-out line FL2 may be arranged between the first organic insulating layer OIL1 and the second organic insulating layer OIL2. The second-1 sub-line FL2a may be disposed on the same layer as the first connection electrode CD1 in the display area DA and may include the same material as the first connection electrode CD1. The second-2 sub-line FL2b may be arranged between the first inorganic insulating layer 213 and the second inorganic insulating layer 215. The second-2 sub-line FL2b may be disposed on the same layer as the first capacitor electrode CE1 and the first gate electrode GE1, which are arranged in the display area DA, and may include the same material as the first capacitor electrode CE1 and the first gate electrode GE1.

In an embodiment and in a plan view, the second-1 sub-line FL2a and the second-2 sub-line FL2b of the second fan-out line FL2 may be electrically connected to each other in a second contact portion CTP2. The second-1 sub-line FL2a of the second fan-out line FL2 may be electrically connected to the second-2 sub-line FL2b through a first connection member CM1. The second-1 sub-line FL2a of the second fan-out line FL2 may be electrically connected to the first connection member CM1 through a contact hole CT3. The first connection member CM1 may be electrically connected to the second-2 sub-line FL2b through a contact hole CT2. The first connection member CM1 may be arranged between the fifth inorganic insulating layer 219 and the first organic insulating layer OIL1. The first connection member CM1 may be disposed on the same layer as the first source electrode SE1, the first drain electrode DE1, the second source electrode SE2, and the second drain electrode DE2, and may include the same material as the first source electrode SE1, the first drain electrode DE1, the second source electrode SE2, and the second drain electrode DE2.

In an embodiment and as described above, as the first fan-out line FL1 includes the first-1 sub-line FL1a and the first-2 sub-line FL1b, which are disposed on different layers, the resistance of the line may be reduced. As the second fan-out line FL2 includes the second-1 sub-line FL2a and the second-2 sub-line FL2b, which are disposed on different layers, the resistance of the line may be reduced.

In an embodiment and referring to FIG. 5, in a plan view, the contact portion CTP of the fan-out line FL may be positioned outside the sealing member 500 (refer to FIG. 3B). For example, the first contact portion CTP1 of the first fan-out line FL1 may be positioned between the sealing member 500 and the pad area PADA. The second contact portion CTP2 of the second fan-out line FL2 may be positioned between the sealing member 500 and the pad area PADA. Accordingly, even when a laser beam is used in a process of bonding the sealing member 500 to the sealing substrate 400, the first sub-line of the fan-out line FL disposed on the inorganic insulating layer 200 (refer to FIGS. 7 and 8), for example, the first-1 sub-line FL1a of the first fan-out line FL1 and the second-1 sub-line FL2a of the second fan-out line FL2, may be prevented from being damaged by the laser beam, that is, the resistance of the first-1 sub-line FL1a of the first fan-out line FL1 and the second-1 sub-line FL2a of the second fan-out line FL2 may be prevented from increasing.

In an embodiment and as described above, the second fan-out line FL2 may be disposed on a different layer from the first fan-out line FL1. For example, the second-1 sub-line FL2a of the second fan-out line FL2 may be disposed on a different layer from the first-1 sub-line FL1a of the first fan-out line FL1. The second-2 sub-line FL2b of the second fan-out line FL2 may be disposed on a different layer from the first-2 sub-line FL1b of the first fan-out line FL1. However, the invention is not limited thereto. In another embodiment, the second-1 sub-line FL2a of the second fan-out line FL2 may be disposed on a different layer from the first-1 sub-line FL1a of the first fan-out line FL1, but the second-2 sub-line FL2b of the second fan-out line FL2 may be disposed on the same layer as the first-2 sub-line FL1b of the first fan-out line FL1. In another embodiment, the second-1 sub-line FL2a of the second fan-out line FL2 may be disposed on the same layer as the first-1 sub-line FL1a of the first fan-out line FL1, but the second-2 sub-line FL2b of the second fan-out line FL2 may be disposed on a different layer from the first-2 sub-line FL1b of the first fan-out line FL1.

In an embodiment and referring to FIG. 5, the first-1 power voltage line 21 may include a first sub-power voltage line 21a and a second sub-power voltage line 21b. The first sub-power voltage line 21a may be arranged closer to the pad area PADA than the second sub-power voltage line 21b in a plan view. In other words, the second sub-power voltage line 21b may be arranged closer to the display area DA than the first sub-power voltage line 21a in a plan view.

In an embodiment, the first sub-power voltage line 21a may overlap the first sub-line of the fan-out line FL in a plan view. For example, the first sub-power voltage line 21a may overlap the first-1 sub-line FL1a of the first fan-out line FL1 and the second-1 sub-line FL2a of the second fan-out line FL2 in a plan view. The second sub-power voltage line 21b may overlap the second sub-line of the fan-out line FL in a plan view. For example, the second sub-power voltage line 21b may overlap the first-2 sub-line FL1b of the first fan-out line FL1 and the second-2 sub-line FL2b of the second fan-out line FL2 in a plan view.

In an embodiment, the first-1 power voltage line 21 may include an opening portion 21H in a plan view. A plurality of opening portions 21H may be provided. The plurality of opening portions 21H of the first-1 power voltage line 21 may be positioned in the first sub-power voltage line 21a. In a plan view, the contact portion CTP of the fan-out line FL may be positioned within the opening portion 21H of the first sub-power voltage line 21a. For example, each of the first contact portions CTP1 of the first fan-out lines FL1 may be positioned within a corresponding opening portion 21H among the plurality of opening portions 21H of the first sub-power voltage line 21a in a plan view. Each of the second contact portions CTP2 of the second fan-out lines FL2 may be positioned within a corresponding opening portion 21H among the plurality of opening portions 21H of the first sub-power voltage line 21a in a plan view.

In an embodiment and referring to FIGS. 5, 6C, 6E, and 9, the first sub-power voltage line 21a and the second sub-power voltage line 21b may be disposed on different layers, where the first sub-power voltage line 21a may be inserted into the inorganic insulating layer 200 and the second sub-power voltage line 21b may be disposed on the inorganic insulating layer 200. In an embodiment, the first sub-power voltage line 21a may be arranged between the fourth inorganic insulating layer 218 and the fifth inorganic insulating layer 219. The first sub-power voltage line 21a may be disposed on the same layer as the second gate electrode GE2 of the second transistor TFT2 in the display area DA and may include the same material as the second gate electrode GE2. The second sub-power voltage line 21b may be arranged between the first organic insulating layer OIL1 and the second organic insulating layer OIL2. The second sub-power voltage line 21b may be disposed on the same layer as the first connection electrode CD1 and include the same material as the first connection electrode CD1.

In an embodiment and referring to FIGS. 5, 7, 8, and 9, the first sub-power voltage line 21a may be disposed on a different layer from the first sub-line of the fan-out line FL. For example, the first sub-power voltage line 21a may be disposed on a different layer from the first-1 sub-line FL1a of the first fan-out line FL1. The first sub-power voltage line 21a may be disposed on a different layer from the second-1 sub-line FL2a of the second fan-out line FL2. In addition, the second sub-power voltage line 21b may be disposed on a different layer from the second sub-line of the fan-out line FL. For example, the second sub-power voltage line 21b may be disposed on a different layer from the first-2 sub-line FL1b of the first fan-out line FL1. The second sub-power voltage line 21b may be disposed on a different layer from the second-2 sub-line FL2b of the second fan-out line FL2.

In an embodiment and referring to FIGS. 5 and 9, the first sub-power voltage line 21a of the first-1 power voltage line 21 may be electrically connected to the second sub-power voltage line 21b through a second connection member CM2. The second sub-power voltage line 21b may be electrically connected to the second connection member CM2 through a contact hole CT5. The second connection member CM2 may be electrically connected to the first sub-power voltage line 21a through a contact hole CT4. The second connection member CM2 may be arranged between the fifth inorganic insulating layer 219 and the first organic insulating layer OIL1. The second connection member CM2 may be disposed on the same layer as the first source electrode SE1, the first drain electrode DE1, the second source electrode SE2, and the second drain electrode DE2, and may include the same material as the first source electrode SE1, the first drain electrode DE1, the second source electrode SE2, and the second drain electrode DE2.

According to an embodiment, the fan-out line FL may include the first sub-line disposed on the inorganic insulating layer 200 and the second sub-line inserted into the inorganic insulating layer 200, the first-1 power voltage line 21 at least partially overlapping the fan-out line FL may include the first sub-power voltage line 21a inserted into the inorganic insulating layer 200 and the second sub-power voltage line 21b disposed on the inorganic insulating layer 200, the first sub-power voltage line 21a of the first-1 power voltage line 21 may overlap the first sub-line of the fan-out line FL, but may be disposed on a different layer from the first sub-line, and the second sub-power voltage line 21b of the first-1 power voltage line 21 may overlap the second sub-line of the fan-out line FL, but may be disposed on a different layer from the second sub-line. In addition, in a plan view, the contact portion CTP to which the first sub-line and the second sub-line of the fan-out line FL are electrically connected may be arranged within the opening portion 21H of the first-1 power voltage line 21. According to an embodiment, as the fan-out line FL includes the first sub-line and the second sub-line, which are disposed on different layers, the resistance of the line may be reduced. At the same time, the fan-out line FL may be designed to overlap the first-1 power voltage line 21 without changing a path, thereby reducing a dead space of a display apparatus.

The display apparatus according to the embodiment may be applied to various electronic devices. An electronic device according to an embodiment of the present disclosure may include the display apparatus (e.g., the display apparatus of FIG. 1) described above, and may further include modules or apparatuses having additional functions in addition to the display apparatus.

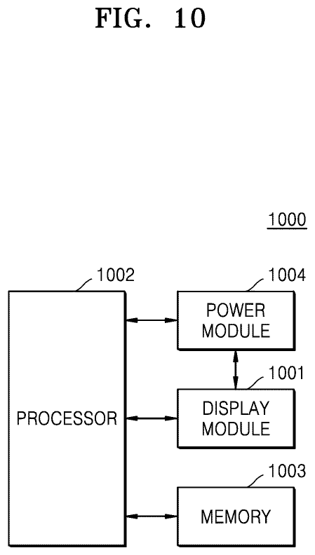

FIG. 10 is a block diagram of an electronic device according to an embodiment.

Referring to FIG. 10, an electronic device 1000 according to an embodiment may include a display module 1001, a processor 1002, a memory 1003, and a power module 1004.

The processor 1002 may include at least one of a central processing unit (CPU), an application processor (AP), a graphic processing unit (GPU), a communication processor (CP), an image signal processor (ISP), and a controller.

The memory 1003 may store data information necessary for the operation of the processor 1002 or the display module 1001. When the processor 1002 executes an application stored in the memory 1003, an image data signal and/or an input control signal may be transmitted to the display module 1001, and the display module 1001 may process a signal received and output image information through a display screen.

The power module 1004 may include a power supply module such as a power adapter or a battery device, and a power conversion module that converts the power supplied by the power supply module to generate power necessary for the operation of the electronic device 1000.

At least one of the components of the electronic device 1000 described above may be included in the display apparatus according to the embodiments described above. In addition, a part among the individual modules functionally included in one module may be included in the display apparatus, and another part may be provided separately from the display apparatus. For example, the display apparatus may include the display module 1001, and the processor 1002, the memory 1003, and the power module 1004 may be provided in the form of other apparatuses within the electronic device 1000 except for the display apparatus.

In an embodiment, the display module 1001 included in the display apparatus may drive based on the image data signal and the input control signal received from the processor 1002.

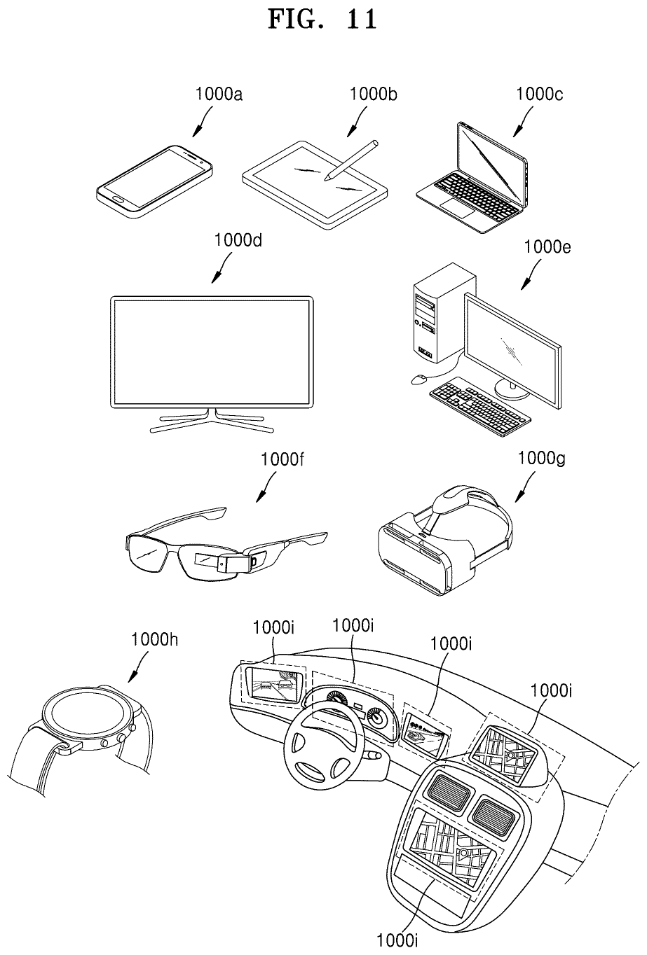

FIG. 11 is schematic diagrams of electronic devices according to various embodiments.

Referring to FIG. 11, various electronic devices to which display apparatuses according to embodiments are applied may include not only image display electronic devices such as a smart phone 1000a, a tablet PC 1000b, a laptop 1000c, a TV 1000d, and a desk monitor 1000e, but also a wearable electronic device including display modules such as smart glasses 1000f, a head mounted display 1000g, and a smart watch 1000h, and a vehicle electronic device 1000i including a dashboard, a center fascia, and display modules such as a CID (Center Information Display) and a room mirror display disposed in the dashboard.

According to the embodiments described above, in a plan view, a fan-out line may be arranged to overlap a power voltage line, thereby reducing a peripheral area of a display apparatus. In addition, the line resistance of the fan-out line and the power voltage line may be reduced to implement a display apparatus with excellent display quality. The scope of the invention is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the invention. Moreover, the embodiments or parts of the embodiments may be combined in whole or in part without departing from the scope of the invention.

What is claimed is:

1. A display apparatus comprising:
a substrate comprising a display area, and a peripheral area comprising a pad area arranged outside of the display area;
an inorganic insulating layer disposed on the substrate;
a light-emitting element layer disposed on the inorganic insulating layer and comprising a light-emitting element overlapping the display area in a plan view;
a power voltage line arranged between the pad area and the display area in a plan view and comprising an opening portion; and
a fan-out line extending from the pad area to the display area and overlapping at least a portion of the power voltage line in a plan view,
wherein the fan-out line comprises a first sub-line disposed on the inorganic insulating layer, a second sub-line inserted into the inorganic insulating layer, and a contact portion in which the first sub-line and the second sub-line are electrically connected, and
wherein the contact portion of the fan-out line is positioned within the opening portion of the power voltage line in a plan view.

2. The display apparatus of claim 1, further comprising an organic insulating layer disposed on the inorganic insulating layer and comprising a first organic insulating layer and a second organic insulating layer, which are sequentially stacked,
wherein,
the inorganic insulating layer comprises a first inorganic insulating layer, a second inorganic insulating layer, and a third inorganic insulating layer, which are sequentially stacked,
the first sub-line of the fan-out line is arranged between the inorganic insulating layer and the first organic insulating layer or between the first organic insulating layer and the second organic insulating layer, and
the second sub-line of the fan-out line is arranged between the first inorganic insulating layer and the second inorganic insulating layer or between the second inorganic insulating layer and the third inorganic insulating layer.

3. The display apparatus of claim 2, further comprising:
a semiconductor layer overlapping the display area in a plan view and arranged between the substrate and the first inorganic insulating layer; and
a gate electrode overlapping the semiconductor layer in a plan view and arranged between the first inorganic insulating layer and the second inorganic insulating layer.

4. The display apparatus of claim 1, wherein the fan-out line comprises first fan-out lines and second fan-out lines, which are alternately arranged, wherein
a first sub-line of each of the first fan-out lines is disposed on a different layer from a first sub-line of each of the second fan-out lines, and
a second sub-line of each of the first fan-out lines is disposed on a different layer from a second sub-line of each of the second fan-out lines.

5. The display apparatus of claim 2, wherein the power voltage line comprises a first sub-power voltage line inserted into the inorganic insulating layer, and a second sub-power voltage line disposed on the inorganic insulating layer and electrically connected to the first sub-power voltage line, wherein
the first sub-power voltage line of the power voltage line overlaps the first sub-line of the fan-out line in a plan view, and
the second sub-power voltage line of the power voltage line overlaps the second sub-line of the fan-out line in a plan view.

6. The display apparatus of claim 5, wherein the opening portion of the power voltage line is positioned in the first sub-power voltage line of the power voltage line.

7. The display apparatus of claim 5, wherein the inorganic insulating layer further comprises a fourth inorganic insulating layer disposed on the third inorganic insulating layer, and
the first sub-power voltage line of the power voltage line is arranged between the third inorganic insulating layer and the fourth inorganic insulating layer.

8. The display apparatus of claim 1, wherein a width of the power voltage line is greater than a width of the fan-out line.

9. The display apparatus of claim 1, further comprising:
a sealing substrate disposed on the light-emitting element layer; and
a sealing member arranged between the substrate and the sealing substrate and surrounding the display area in a plan view,
wherein the fan-out line extends across the sealing member in a plan view, and
the contact portion of the fan-out line is positioned between the sealing member and the pad area.

10. The display apparatus of claim 1, further comprising an encapsulation layer disposed on the light-emitting element layer and comprising at least one inorganic encapsulation layer and at least one organic encapsulation layer.

11. The display apparatus of claim 1, wherein the fan-out line comprises a plurality of fan-out lines,
the power voltage line comprises a plurality of opening portions, and
the contact portion of each of the plurality of fan-out lines is positioned within a corresponding opening portion among the plurality of opening portions.

12. A display apparatus comprising:
a substrate comprising a display area and a peripheral area comprising a pad area arranged outside of the display area;
an inorganic insulating layer disposed on the substrate;
a light-emitting element layer disposed on the inorganic insulating layer and comprising a light-emitting element overlapping the display area in a plan view;
a power voltage line arranged between the pad area and the display area in a plan view; and
a fan-out line extending from the pad area to the display area and overlapping at least a portion of the power voltage line in a plan view,
wherein,
the fan-out line comprises a first sub-line disposed on the inorganic insulating layer, a second sub-line inserted into the inorganic insulating layer, and a contact portion in which the first sub-line and the second sub-line are electrically connected,
the power voltage line comprises a first sub-power voltage line inserted into the inorganic insulating layer, and a second sub-power voltage line disposed on the inorganic insulating layer and electrically connected to the first sub-power voltage line,
the first sub-power voltage line of the power voltage line overlaps the first sub-line of the fan-out line in a plan view,
the second sub-power voltage line of the power voltage line overlaps the second sub-line of the fan-out line in a plan view, and
the first sub-power voltage line of the power voltage line is disposed on a different layer from the first sub-line of the fan-out line.

13. The display apparatus of claim 12, further comprising an organic insulating layer disposed on the inorganic insulating layer and comprising a first organic insulating layer and a second organic insulating layer, which are sequentially stacked,
wherein,
the inorganic insulating layer comprises a first inorganic insulating layer, a second inorganic insulating layer, and a third inorganic insulating layer, which are sequentially stacked,
the first sub-line of the fan-out line is arranged between the inorganic insulating layer and the first organic insulating layer or between the first organic insulating layer and the second organic insulating layer, and
the second sub-line of the fan-out line is arranged between the first inorganic insulating layer and the second inorganic insulating layer or between the second inorganic insulating layer and the third inorganic insulating layer.

14. The display apparatus of claim 13, further comprising:
a semiconductor layer overlapping the display area in a plan view and arranged between the substrate and the first inorganic insulating layer; and
a gate electrode overlapping the semiconductor layer in a plan view and arranged between the first inorganic insulating layer and the second inorganic insulating layer.

15. The display apparatus of claim 13, wherein the inorganic insulating layer further comprises a fourth inorganic insulating layer disposed on the third inorganic insulating layer, and
the first sub-power voltage line of the power voltage line is arranged between the third inorganic insulating layer and the fourth inorganic insulating layer.

16. The display apparatus of claim 12, wherein the first sub-power voltage line of the power voltage line comprises an opening portion.

17. The display apparatus of claim 16, wherein the contact portion of the fan-out line is positioned within the opening portion of the first sub-power voltage line in a plan view.

18. The display apparatus of claim 12, wherein the fan-out line comprises first fan-out lines and second fan-out lines, which are alternately arranged, wherein
a first sub-line of each of the first fan-out lines is disposed on a different layer from a first sub-line of each of the second fan-out lines, and
a second sub-line of each of the first fan-out lines is disposed on a different layer from a second sub-line of each of the second fan-out lines.

19. An electronic device comprising a display apparatus,
wherein the display apparatus comprises:
a substrate comprising a display area, and a peripheral area comprising a pad area arranged outside of the display area;
an inorganic insulating layer disposed on the substrate;
a light-emitting element layer disposed on the inorganic insulating layer and comprising a light-emitting element overlapping the display area in a plan view;
a power voltage line arranged between the pad area and the display area in a plan view and comprising an opening portion; and
a fan-out line extending from the pad area to the display area and overlapping at least a portion of the power voltage line in a plan view,
wherein the fan-out line comprises a first sub-line disposed on the inorganic insulating layer, a second sub-line inserted into the inorganic insulating layer, and a contact portion in which the first sub-line and the second sub-line are electrically connected, and
wherein the contact portion of the fan-out line is positioned within the opening portion of the power voltage line in a plan view.

20. The electronic device of claim 19, further comprising:
a display module;
a processor;
a power module; and
a memory,
wherein the display apparatus includes one of the display module, the processor, the power module, or the memory.
